(19) United States
(12) Patent Application Publication
(10) Pub. No.: US 2026/0215055 A1
(43) Pub. Date: Jul. 23, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: DONGHYUN LEE, Yongin-si (KR); MINSANG KOO, Yongin-si (KR); SI JOON SONG, Yongin-si, Gyeonggi-do (KR)

(21) Appl. No.: 19/392,480

(22) Filed: Nov. 18, 2025

(30) Foreign Application Priority Data
Jan. 21, 2025 (KR) 10-2025-0008825

(51) Int. Cl. H10H 29/41; H10H 29/37; H10K 59/124; H10K 59/131

(52) U.S. Cl. CPC H10H 29/41; H10H 29/37; H10K 59/124; H10K 59/131

(57) ABSTRACT

A display device includes a display panel and a circuit board electrically connected to the display panel. The display panel includes a light emitting element layer, a circuit layer, and a base layer including a base layer opening portion exposing a portion of a bottom surface of the circuit layer. The circuit layer includes a first pad insulating layer including a first pad insulating layer opening portion corresponding to the base layer opening portion. An etch stopper layer is disposed on the first pad insulating layer and includes a portion exposed by the first pad insulating layer opening portion. The display panel further includes a pad electrode disposed inside the first pad insulating layer opening portion and including a protrusion protruding in a direction from the light emitting element layer towards the circuit layer.

### CROSS-REFERENCE TO RELATED APPLICATIONS

This application claims priority under 35 U.S.C. § 119 to Korean Patent Application No. 10-2025-0008825, filed on January 21, 2025 in the Korean Intellectual Property Office, the disclosure of which is incorporated by reference in its entirety herein.

### 1. TECHNICAL FIELD

The present disclosure herein relates to a display device and an electronic device including the same, and more particularly, to a display device including a display panel and a circuit board, and an electronic device including the display device.

### 2. DISCUSSION OF RELATED ART

An electronic device includes a display area activated in response to an electrical signal. The electronic device may sense inputs applied from the outside (e.g., the external environment) through the display area and also may display various still and/or moving images to provide information for users.

The electronic device includes a display panel and a circuit board. The display panel may be connected to a main board through the circuit board.

### SUMMARY

The present disclosure provides a display device with increased bonding reliability of a display panel and a circuit board, and an electronic device including the display device.

According to an embodiment of the present inventive concept, a display device includes a display panel having a display area and a non-display area adjacent to the display area. The non-display area includes a pad area. A circuit board is electrically connected to the display panel. The display panel includes a light emitting element layer comprising a light emitting element. Aa circuit layer is disposed below the light emitting element layer. The circuit layer comprises a top surface in contact with the light emitting element layer and a bottom surface opposing the top surface. A base layer is disposed below the circuit layer. The base layer includes a base layer opening portion overlapping the pad area and exposing a portion of the bottom surface of the circuit layer. The circuit layer comprises a first pad insulating layer directly contacting the base layer. The first pad insulating layer includes a first pad insulating layer opening portion corresponding to the base layer opening portion. An etch stopper layer is disposed on the first pad insulating layer. The etch stopper layer has a portion exposed by the first pad insulating layer opening portion. The display panel further comprises a pad electrode disposed inside the first pad insulating layer opening portion and comprising a protrusion protruding in a direction from the light emitting element layer towards the circuit layer.

In an embodiment, the circuit layer may further include a second pad insulating layer disposed above the etch stopper layer.

In an embodiment, the pad electrode may be disposed below the second pad insulating layer, and the etch stopper layer includes an etch stopper layer opening portion exposing the pad electrode.

In an embodiment, the first pad insulating layer may include at least one inorganic layer, and the second pad insulating layer may include at least one organic layer.

In an embodiment, the second pad insulating layer may further include at least one inorganic layer disposed below the at least one organic layer.

In an embodiment, the first pad insulating layer may further include at least one organic layer disposed above the at least one inorganic layer.

In an embodiment, the etch stopper layer opening portion may include a plurality of etch stopper layer opening portions.

In an embodiment, the second pad insulating layer may include a (2-1)-th pad insulating layer in direct contact with the etch stopper layer, and a (2-2)-th pad insulating layer disposed above the (2-1)-th pad insulating layer. The pad electrode may be disposed below the (2-2)-th pad insulating layer. The etch stopper layer includes an etch stopper layer opening portion exposing the pad electrode. A (2-1)-th pad insulating layer includes a (2-1)-th pad insulating layer opening portion corresponding to the etch stopper layer opening portion.

In an embodiment, the etch stopper layer opening portion may include a plurality of eth stopper layer opening portions. The (2-1)-th pad insulating layer opening portion may include a plurality of (2-1)-th pad insulating layer opening portions. Each of the plurality of (2-1)-th pad insulating opening portions correspond to each of the plurality of etch stopper layer opening portions.

In an embodiment, the pad electrode may be disposed between the second pad insulating layer and the etch stopper layer.

In an embodiment, the etch stopper layer includes an etch stopper layer opening portion exposing a portion of the pad electrode.

In an embodiment, the first pad insulating layer may include a (1-1)-th pad insulating layer in direct contact with the base layer, and a (1-2)-th pad insulating layer disposed on the (1-1)-th pad insulating layer. The pad electrode may be disposed below the (1-2)-th pad insulating layer. The (1-1)-th pad insulating layer includes a first pad insulating layer opening portion. The (1-2)-th pad insulating layer includes a (1-2)-th pad insulating layer opening portion overlapping the first pad insulating layer opening portion and surrounding the pad electrode.

In an embodiment, the circuit layer may further include an auxiliary etch stopper layer disposed between the (1-1)-th pad insulating layer and the (1-2)-th pad insulating layer. The auxiliary etch stopper layer has a thickness that is less than a thickness of the etch stopper layer. The auxiliary etch stopper layer may not overlap the (1-2)-th pad insulating layer opening portion on a plane. The auxiliary etch stopper layer includes an auxiliary etch stopper layer opening portion exposing the pad electrode.

In an embodiment, the base layer may include a glass substrate, the etch stopper layer may include amorphous silicon, silicon nitride, or polyimide, and the pad electrode may include molybdenum, tungsten, titanium, or amorphous silicon.

In an embodiment, the display device may further include an adhesive layer disposed between the display panel and the circuit board, and the circuit board may include a base film, and a bump electrode disposed on the base film and overlapping the pad electrode on a plane. The adhesive layer may include an adhesive resin in direct contact with each of the display panel and the circuit board, and a conductive particle disposed in the adhesive resin and electrically connected to the pad electrode and the bump electrode.

According to an embodiment of the present disclosure, a display device includes a display panel including a display area and a non-display area adjacent to the display area, the non-display area including a pad area. A circuit board is electrically connected to the display panel. The display panel includes a light emitting element layer comprising a light emitting element. A circuit layer is disposed below the light emitting element layer. The circuit layer comprises a top surface in contact with the light emitting element layer and a bottom surface opposing the top surface. A base layer is disposed below the circuit layer. The base layer includes a base layer opening portion overlapping the pad area and exposing a portion of the bottom surface of the circuit layer. The circuit layer comprises a first pad insulating layer directly contacting the base layer. The first pad insulating layer includes a first pad insulating layer opening portion corresponding to the base layer opening portion. An etch stopper layer is disposed on the first pad insulating layer. The etch stopper layer has a portion exposed by the first pad insulating layer opening portion. The display panel further comprises a pad electrode disposed inside the first pad insulating layer opening portion and comprising a recess recessed in a direction from the circuit layer towards the light emitting element layer.

In an embodiment, the circuit layer may further include a second pad insulating layer disposed above the etch stopper layer, and the pad electrode may be disposed below the etch stopper layer.

In an embodiment, the first pad insulating layer may include at least one inorganic layer, and the second pad insulating layer may include at least one organic layer.

In an embodiment, the base layer may include a glass substrate, the etch stopper layer may include amorphous silicon, silicon nitride, or polyimide, and the pad electrode may include molybdenum, tungsten, titanium, or amorphous silicon.

According to an embodiment of the present disclosure, an electronic device includes a display panel having a display area and a non-display area adjacent to the display area. The non-display area includes a pad area. A circuit board is disposed below the display panel and is electrically connected to the display panel. A window is disposed on the display panel, and comprises a transmission area overlapping the display area and a bezel area overlapping the non-display area. A housing is disposed below the display panel to accommodate the display panel and the circuit board, and is coupled to the window. The display panel comprises a light emitting element layer comprising a light emitting element. A circuit layer is disposed below the light emitting element layer. The circuit layer comprises a top surface in contact with the light emitting element layer and a bottom surface opposing to the top surface. A base layer is disposed below the circuit layer. The base layer includes a base layer opening portion overlapping the pad area and exposing a portion of the bottom surface of the circuit layer. The circuit layer comprises a first pad insulating layer directly contacting the base layer, and the first pad insulating layer including a first pad insulating layer opening portion corresponding to the base layer opening portion. An etch stopper layer is disposed on the first pad insulating layer. The etch stopper layer has a portion exposed by the first pad insulating layer opening portion. A second pad insulating layer is disposed on the etch stopper layer. The display panel further comprises a pad electrode disposed inside the first pad insulating layer opening portion.

### BRIEF DESCRIPTION OF THE DRAWINGS

The accompanying drawings are included to provide a further understanding of the present inventive concept, and are incorporated in and constitute a part of this specification. The drawings illustrate non-limiting embodiments of the present inventive concept and, together with the description, serve to explain principles of the present inventive concept. In the drawings:

FIG. 1 is an assembled perspective view of an electronic device according to an embodiment of the present inventive concept;

FIG. 2 is an exploded perspective view of an electronic device according to an embodiment of the present inventive concept;

FIG. 3 is a cross-sectional view of a display device according to an embodiment of the present inventive concept;

FIG. 4 is a schematic cross-sectional view of a display module according to an embodiment of the present inventive concept;

FIG. 5 is a plan view of a display panel according to an embodiment of the present inventive concept;

FIG. 6 is a cross-sectional view of a display module according to an embodiment of the present inventive concept;

FIG. 7 is a plan view of a display panel according to an embodiment of the present inventive concept;

FIG. 8 is a cross-sectional view of a display device according to an embodiment of the present inventive concept;

FIG. 9 is an enlarged cross-sectional view of a portion of a display device according to an embodiment of the present inventive concept;

FIGS. 10A to 10D are each a cross-sectional view illustrating one step of a method for manufacturing a display device according to embodiments of the present inventive concept;

FIGS. 11A to 16J are each an enlarged cross-sectional view of a portion of a display panel according to embodiments of the present inventive concept;

FIG. 17 is a block diagram of an electronic device according to an embodiment of the present inventive concept; and

FIG. 18 is a schematic view of electronic devices according to various embodiments of the present inventive concept.

### DETAILED DESCRIPTION OF EMBODIMENTS

The present inventive concept may be modified in various forms, and non-limiting embodiments thereof will be illustrated in the drawings and described herein in detail. The present inventive concept should not be construed as limited to the described embodiments set forth herein.

In this specification, it will be understood that when an element (or a region, a layer, a portion, or the like) is referred to as being "on", "connected to" or "coupled to" another element, it may be directly disposed on, connected to, or coupled to the other element, or other elements may be disposed therebetween. When an element is referred to as being "directly on", "directly connected to" or "directly coupled to" another element, no intervening elements may be present.

Like reference numerals or symbols refer to like elements throughout. In the drawings, the thickness, ratio, and size of the elements may be exaggerated for effectively describing the technical contents.

As used herein, the term "and/or" includes any and all combinations of one or more of the associated listed elements.

It will be understood that, although the terms "first", "second", etc. may be used herein to describe various elements, the elements are not to be limited by these terms. These terms are only used to distinguish one element, component, region, layer or section from another element, component, region, layer or section. For instance, a first element, component, region, layer or section discussed below could be termed a second element, component, region, layer or section without departing from the scope of the present inventive concept. Similarly, a second element, component, region, layer or section could be termed a first element, component, region, layer or section. In this specification, the singular expressions "a", "an" and "the" are intended to include the plural forms as well, unless the context clearly indicates otherwise.

In addition, the terms "below", "under", "on the lower side", "above", “over”, "on the upper side", or the like may be used to describe the relationships between the elements illustrated in the drawings. These terms are relative concepts and are described on the basis of the directions indicated in the drawings.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms "comprises, includes, has" and/or "comprising, including, having", when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Hereinafter, non-limiting embodiments of the present inventive concept will be described with reference to the accompanying drawings.

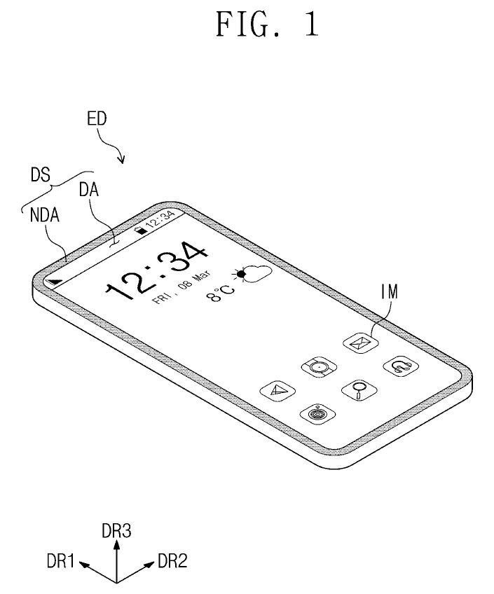

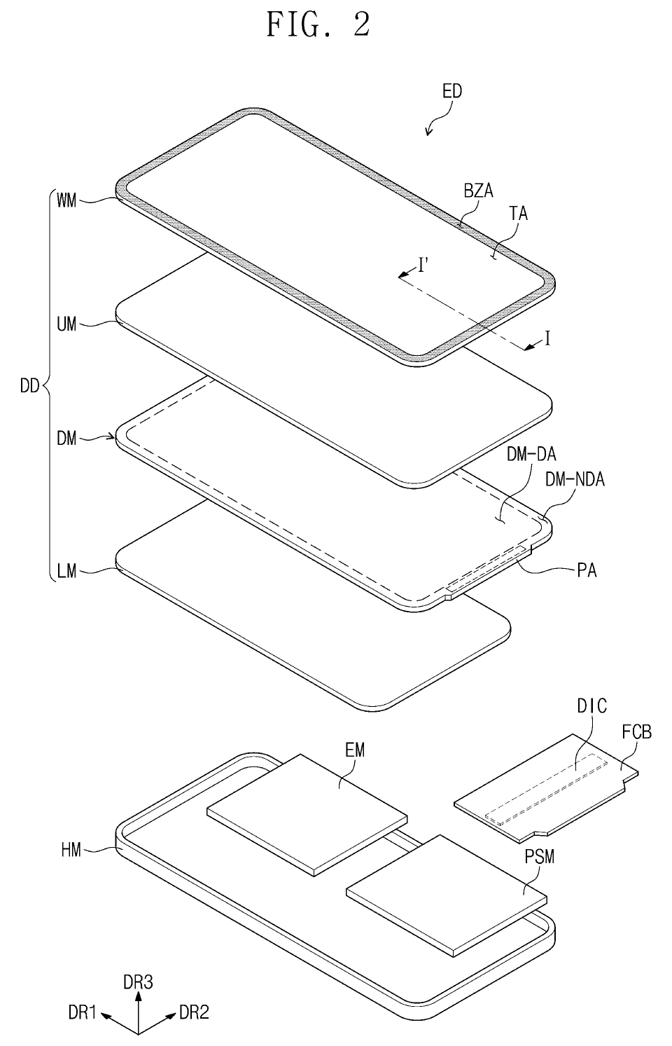

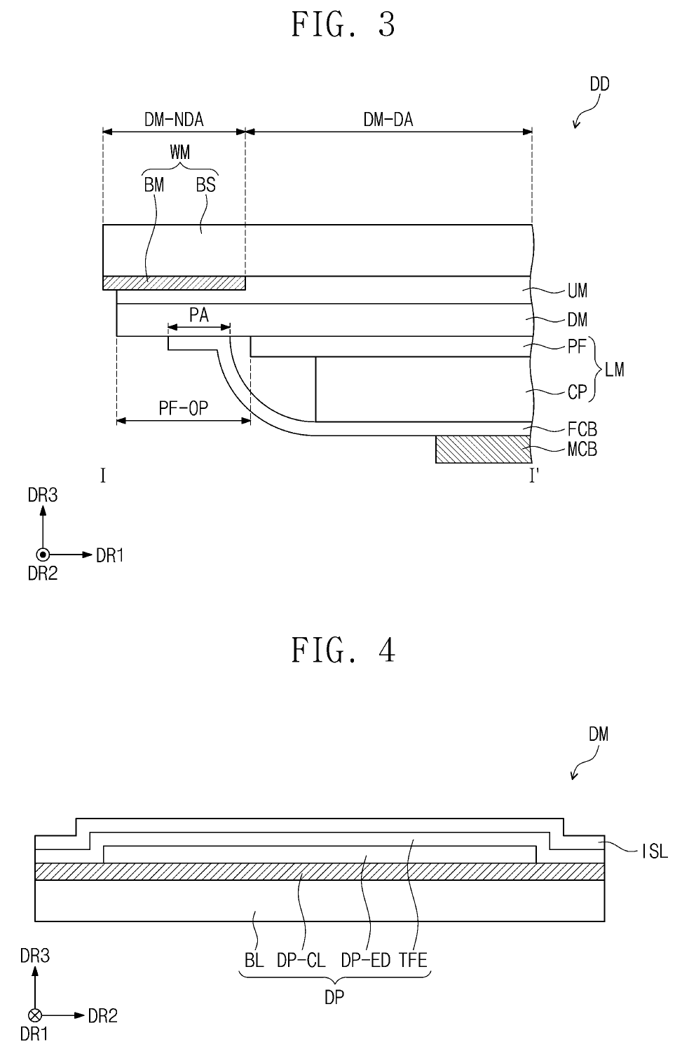

FIG. 1 is an assembled perspective view of an electronic device ED according to an embodiment of the present inventive concept. FIG. 2 is an exploded perspective view of the electronic device ED according to an embodiment of the present inventive concept. FIG. 3 is a cross-sectional view of the electronic device ED according to an embodiment of the present inventive concept.

The present disclosure concerns a display device includes a pad electrode having a protrusion or recess. A circuit board is backside bonded to a display panel of the display device by being coupled to the pad electrode. A first pad insulating layer may be disposed on a base layer and includes an opening portion corresponding to a base layer opening portion. An etch stopper layer may be disposed on the first pad insulating layer and has a portion exposed by the first insulating layer opening portion. A second pad insulating layer may be disposed on the etch stopper layer and may not include an opening portion in the pad area.

The pad electrode compensates for a stepped portion of the bump electrode and provides a more stable contact structure. Therefore, contact resistance may be reduced and the embedding degree of a conductive particle may be increased. The pad electrode prevent slips during the bonding process of the display panel and the circuit board.

Referring to FIG. 1, the electronic device ED according to an embodiment of the present inventive concept may include a display surface DS extending in a first direction DR1 and a second direction DR2 crossing the first direction DR1. For example, in an embodiment the first and second directions DR1, DR2 may be perpendicular to each other. However, embodiments of the present disclosure are not necessarily limited thereto. The electronic device ED may provide an image IM for a user through the display surface DS.

The display surface DS may include a display area DA and a non-display area NDA around the display area DA (e.g., in a plan view). The display area DA may be an area which displays the image IM, and the non-display area NDA may be an area which does not display the image IM. The non-display area NDA may surround the display area DA (e.g., in a plan view). However, embodiments of the present inventive concept are not necessarily limited thereto, and a shape of the display area DA and a shape of the non-display area NDA may be changed.

Hereinafter, a direction substantially perpendicularly crossing a plane defined by the first direction DR1 and the second direction DR2 is defined as a third direction DR3. The third direction DR3 serves as a basis for distinguishing a front surface and a rear surface of each member. The phrase "on a plane" or “in a plan view” used herein may be defined as being in a state in which the electronic device ED is viewed in the third direction DR3.

In an embodiment of the present inventive concept, the electronic device ED may be a foldable electronic device capable of being folded around a folding axis. In an embodiment, the folding axis may be parallel to the first direction DR1 or the second direction DR2, and a folding area may be defined in a portion of the display area DA. The electronic device ED may be in-folded so that portions of the display area DA face each other, or be out-folded so that the portions of the display area DA are away from each other.

Referring to FIG. 2, in an embodiment the electronic device ED may include a display device DD, an electronic module EM, a power module PSM, and a housing HM. FIG. 2 illustrates the electronic device ED in brief, and the electronic device ED may further include a mechanical structure (e.g., a hinge) for controlling an operation (e.g., folding or rolling) of the display device DD.

The display device DD generates the image IM and senses an external input. In an embodiment, the display device DD includes a window WM, an upper member UM, a display module DM, a lower member LM, a circuit board (or flexible circuit board) FCB, and a driving chip DIC. The upper member UM includes members disposed above the display module DM, and the lower member LM includes members disposed below the display module DM.

The window WM provides a front surface of the electronic device ED. The window WM includes a transmission area TA and a bezel area BZA. The display area DA and the non-display area NDA of the display surface DS illustrated in FIG. 1 are defined by the transmission area TA and the bezel area BZA. The transmission area TA is an area through which an image passes, and the bezel area BZA is an area which covers a structure/member disposed below the window WM.

The display module DM includes a display area DM-DA and a non-display area DM-NDA respectively corresponding to the display area DA and the non-display area NDA illustrated in FIG. 1. In the present disclosure, when "a region/portion corresponds to another region/portion", it means that the regions/portions overlap each other, and is not necessarily limited to the meaning that the regions/portions have the same surface area (e.g., in a plan view).

A pad area PA is disposed on one side of the non-display area DM-NDA. The pad area PA is an area electrically bonded (or connected) to the circuit board FCB to be described later. In this embodiment, the pad area PA is defined on a rear surface of the display module DM.

In an embodiment, the display module DM has a substantially rectangular shape. Here, the "substantially rectangular shape" includes not only a rectangular shape in terms of mathematics, but also a rectangle-like shape which may be perceived as a rectangle by a user. For example, the substantially rectangular shape may include a rectangular shape having rounded corner areas. In addition, in the substantially rectangular shape, an edge of a display panel DP is not necessarily limited to a straight line, and the edge may include a curved area.

The upper member UM may include a protective film or an optical film. The optical film may include a polarizer and a retarder to reduce the reflectance of external light. The lower member LM may include a protective film which protects the display panel DP, a support member which supports the display panel DP, a digitizer, and the like. The upper member UM and the lower member LM will be described later in detail.

The circuit board FCB is disposed below the display module DM (e.g., in a direction opposite to the third direction DR3). The circuit board FCB may be bonded to a rear surface of the display panel DP. The circuit board FCB electrically connects the display panel DP to a main circuit board MCB (see FIG. 3). The circuit board FCB includes at least one insulating layer and at least one conductive layer. The conductive layer may include a plurality of signal lines.

In an embodiment, the driving chip DIC may be mounted on the circuit board FCB. The driving chip DIC may include driving circuits, for example, a data driving circuit, for driving pixels of the display panel DP. FIG. 2 illustrates a structure in which the driving chip DIC is mounted on the circuit board FCB, but embodiments of the present inventive concept are not necessarily limited thereto. For example, the driving chip DIC may be mounted on the display module DM or the main circuit board.

In an embodiment, the electronic module EM may include a control module, a wireless communication module, an image input module, a sound input module, a sound output module, a memory, an external interface module, and the like. The electronic module EM may include a main circuit board, and the foregoing modules may be mounted on the main circuit board or electrically connected to the main circuit board through a flexible circuit board. The electronic module EM is electrically connected to the power module PSM.

In an embodiment, the electronic device ED may further include an electro-optical module. The electro-optical module may be an electronic component for outputting or receiving an optical signal. The electro-optical module may include a camera module and/or a proximity sensor. The camera module may photograph an external image through a partial area of the display panel DP.

The housing HM illustrated in FIG. 2 is coupled to the display device DD, particularly to the window WM, and accommodates the other modules above. The housing HM is illustrated as having a shape of one body, but is not necessarily limited thereto. The housing HM may include a plurality of portions (e.g., side edge portions and a bottom portion) that are coupled to each other.

FIG. 3 is a cross-sectional view of a display device DD taken along line I-I' in FIG. 2. Referring to FIG. 3, a window WM may include a base substrate BS and a bezel pattern BM disposed on a bottom surface of the base substrate BS. The base substrate BS may include a synthetic resin film or a glass substrate. The base substrate BS may have a multilayer structure. In an embodiment, the base substrate BS may include a thin-film glass substrate, a protective film disposed on the thin-film glass substrate, and an adhesive layer which couples the thin-film glass substrate to the protective film.

The bezel pattern BM is a colored light-blocking film and may be formed, for example, by coating. The bezel pattern BM may include a base material and a dye or pigment mixed in the base material. The bezel pattern BM overlaps the non-display region NDA illustrated in FIG. 1 and the bezel area BA illustrated in FIG. 2. The bezel pattern BM may be disposed on the bottom surface of the base substrate BS. When the base substrate BS has a multilayer structure, the bezel pattern BM may be disposed between interfaces defined by a plurality of layers. For example, the bezel pattern BM may be disposed between the thin-film glass substrate and the protective film. In some embodiments, the window WM may further include at least one of a hard coating layer, an anti-fingerprint layer, or an anti-reflective layer on a top surface of the base substrate BS.

An upper member UM may include an upper film. The upper film may include a synthetic resin film. In an embodiment, the synthetic resin film may include polyimide, polycarbonate, polyamide, triacetylcellulose, polymethylmethacrylate, or polyethylene terephthalate.

The upper film may absorb an external impact applied to a front surface of the display device DD. In an embodiment of the present inventive concept, a display module DM may include a color filter which replaces a polarizing film as an anti-reflective member, but in this case, front impact strength of the display device DD may be reduced. The upper film may compensate for the impact strength reduced due to the application of the color filter.

The upper member UM overlaps the bezel area BZA (see FIG. 2) and the transmission area TA (see FIG. 2). In an embodiment, the upper member UM may overlap only a partial area of the bezel area BZA. A portion of the bezel pattern BM may be exposed from the upper member UM. In an embodiment of the present inventive concept, the upper member UM may be omitted. In an embodiment of the present inventive concept, the upper member UM may be replaced with an optical film including a polarizer and a retarder.

In an embodiment, an adhesive layer which couples the upper member UM to the window WM may be further included between the upper member UM and the window WM (e.g., in the third direction DR3). The adhesive layer may be a pressure sensitive adhesive film (PSA) or an optically clear adhesive (OCA).

The display module DM is disposed below the upper member UM (e.g., in a direction opposite to the third direction DR3). The display module DM overlaps the bezel area BZA (see FIG. 2) and the transmission area TA (see FIG. 2). In an embodiment, the display module DM may entirely overlap the upper member UM within the bezel area BZA. A side surface of the display module DM may be aligned with a side surface of the upper member UM, and on a plane, a corner of the display module DM may be aligned with a corner of the upper member UM.

A pad area PA of the display module DM may overlap the upper member UM within the bezel area BZA. A portion of the display module DM, which corresponds to the pad area PA, may be coupled to a bottom surface of the upper member UM through the adhesive layer. As the pad area PA overlaps the upper member UM and the portion, overlapping the pad area PA, of the display module DM is coupled to the upper member UM, the upper member UM may sufficiently support the pad area PA when a circuit board FCB is bonded to the pad area PA.

In an embodiment, a lower member LM may include a lower film PF and a cover panel CP. In an embodiment of the present inventive concept, the lower member LM may further include a support plate and a digitizer.

The lower film PF may expose the pad area PA of the display module DM. The lower film PF may have a smaller size (e.g., area in a plan view) than the display module DM. For example, in an embodiment the lower film PF may overlap only a display area DM-DA of the display module DM. An open area PF-OP corresponding to a non-display area DM-NDA may be defined in the lower film PF. Alternatively, the lower film PF may have a size (e.g., area in a plan view) substantially corresponding to the display module DM. In this case, the open area PF-OP corresponding to the pad area PA may be defined in the lower film PF. The pad area PA may be exposed through the open area PF-OP.

The cover panel CP may be disposed below the lower film PF (e.g., in a direction opposite to the third direction DR3). The cover panel CP may increase resistance against a compressive force generated by pushing from the outside (e.g., pressure exerted from the external environment). Thus, the cover panel CP may serve to prevent the display module DM from being deformed. In an embodiment, the cover panel CP may include a flexible plastic material such as polyimide or polyethylene terephthalate. In addition, the cover panel CP may be a colored film having a low light transmittance. The cover panel CP may absorb light incident from the outside. For example, in an embodiment the cover panel CP may be a black synthetic resin film. When the display device DD is seen from above the window WM, components disposed below the cover panel CP may not be visible to a user.

In an embodiment, a support plate may be further disposed below the cover panel CP (e.g., in a direction opposite to the third direction DR3). The support plate may include a metal material having high strength. The support plate may include a reinforced fiber composite material. The support plate may include a reinforced fiber disposed inside a matrix part. The reinforced fiber may be a carbon fiber or a glass fiber. The matrix part may include a polymer resin. The matrix part may include a thermoplastic resin. For example, in an embodiment the matrix part may include a polyamide-based resin or a polypropylene-based resin. For example, the reinforced fiber composite material may be carbon fiber reinforced plastic (CFRP) or glass fiber reinforced plastic (GFRP).

A main circuit board MCB may be disposed on (e.g., disposed directly thereon) a bottom surface of the circuit board FCB. The circuit board FCB may include an insulating film and conductive lines mounted on the insulating film. The main circuit board MCB may include signal lines and electronic elements. The electronic elements may be connected to the signal lines and electrically connected to the display module DM. The electronic elements generate various electrical signals, for example, a signal for generating an image or a signal for sensing an external input, or process sensed signals. The main circuit board MCB may be provided as a single main circuit board to correspond to each of the electrical signals for the generation and processing, or the main circuit board MCB may be three or more in number and is not necessarily limited to any one embodiment.

The main circuit board MCB may include the driving chip DIC (see FIG. 2) mounted in the main circuit board MCB.

Referring to FIGS. 2 and 3, the circuit board FCB is coupled onto the rear surface of the display panel DP (backside bonding). As the non-display area DM-NDA of the display module DM is not bent, the non-display area DM-NDA of the display panel DP may be prevented against a defect generated upon bending. In addition, a surface area of the bezel area BZA of the window WM for covering the non-display area DM-NDA of the display panel DP may be decreased.

FIG. 4 is a schematic cross-sectional view of a display module DM according to an embodiment of the present inventive concept.

Referring to FIG. 4, in an embodiment the display module DM may include a display panel DP and an input sensing layer ISL. The display panel DP may include a base layer BL, a circuit layer DP-CL, a light emitting element layer DP-ED, and an encapsulation layer TFE.

The circuit layer DP-CL is disposed on (e.g., disposed directly thereon in the third direction DR3) a top surface of the base layer BL. The base layer BL may be a flexible substrate capable of bending, folding, rolling or the like. In an embodiment, the base layer BL may be a glass substrate, a metal substrate, a polymer substrate, or the like. However, embodiments of the present inventive concept are not necessarily limited thereto, and the base layer BL may be an inorganic layer, an organic layer, or a composite material layer. The base layer BL has substantially the same shape as the display panel DP.

The base layer BL may have a multilayer structure. For example, in an embodiment the base layer BL may include a first synthetic resin layer, a second synthetic resin layer, and inorganic layers disposed between the first and second synthetic resin layers. Each of the first and second synthetic resin layers may include a polyimide-based resin, and is not necessarily limited thereto.

The circuit layer DP-CL may be disposed on the base layer BL (e.g., disposed directly thereon in the third direction DR3). The circuit layer DP-CL may include a plurality of insulating layers, a plurality of semiconductor patterns, a plurality of conductive patterns, signal lines, and the like. The circuit layer DP-CL may include a driving circuit of a pixel. Hereinafter, unless separately defined, components A and B being disposed at the same layer is interpreted as being formed through the same process to include the same material or have the same stack structure. Conductive patterns or semiconductor patterns disposed at the same layer may interpreted as described above.

The light emitting element layer DP-ED may be disposed on the circuit layer DP-CL (e.g., disposed directly thereon in the third direction DR3). The light emitting element layer DP-ED may include a light emitting element. For example, in an embodiment the light emitting element may include an organic light emitting material, an inorganic light emitting material, an organic-inorganic light emitting material, a quantum dot, a quantum rod, a micro LED, or a nano LED.

The encapsulation layer TFE may be disposed on (e.g., disposed directly thereon) the light emitting element layer DP-ED. The encapsulation layer TFE may protect the light emitting element layer DP-ED, such as the light emitting element, from moisture, oxygen, and foreign matter such as dust particles. The encapsulation layer TFE may include at least one inorganic encapsulation layer and at least one organic encapsulation layer. In an embodiment, the encapsulation layer TFE may include a stack structure of first inorganic encapsulation layer/organic encapsulation layer/second inorganic encapsulation layer.

In an embodiment, the input sensing layer ISL may be directly disposed on the display panel DP. The input sensing layer ISL may sense a user’s input by using, for example, an electromagnetic induction method or a capacitance method. The display panel DP and the input sensing layer ISL may be formed through a continuous process. Here, the phrase "being directly disposed" may mean that a third component is not disposed between the input sensing layer ISL and the display panel DP (e.g., in the third direction DR3). For example, a separate adhesive layer may not be disposed between the input sensing layer ISL and the display panel DP (e.g., in the third direction DR3).

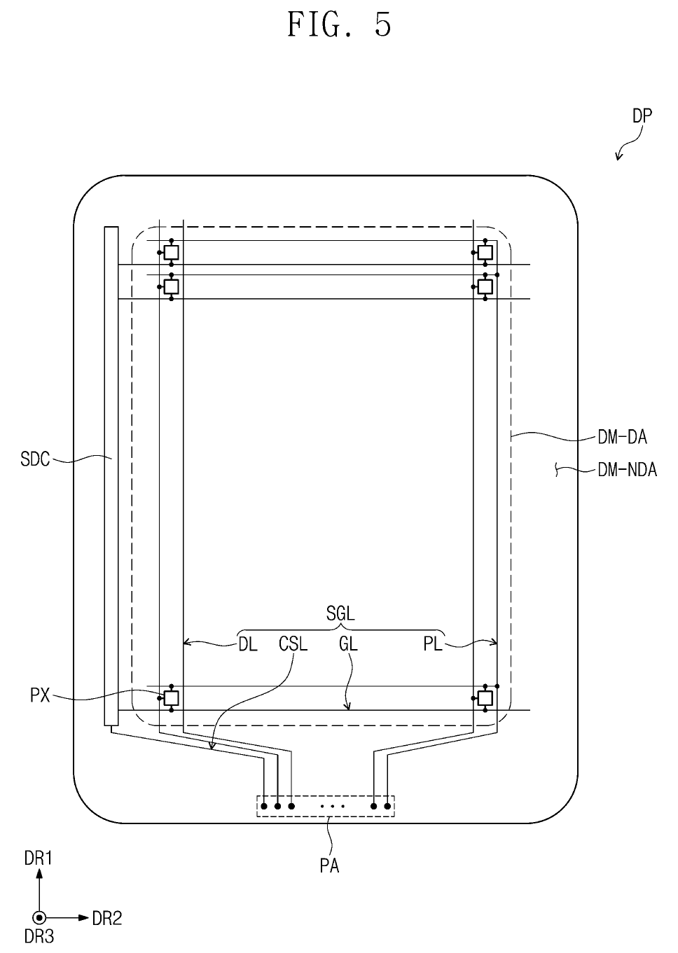

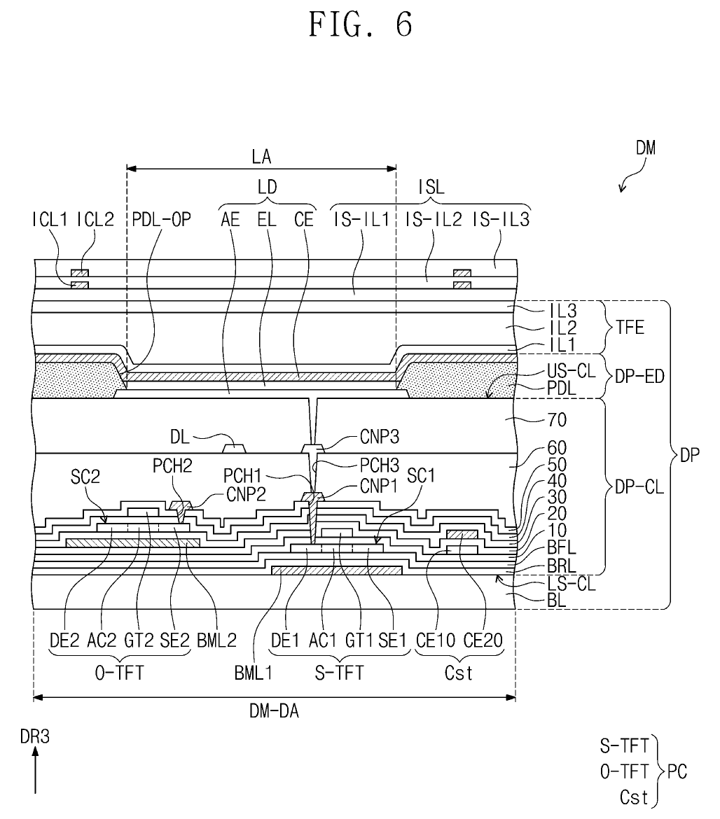

FIG. 5 is a plan view of a display panel DP according to an embodiment of the present inventive concept. FIG. 6 is a cross-sectional view of a display module DM according to an embodiment of the present inventive concept. FIG. 6 illustrates a cross-section of the display module DM corresponding to a pixel PX in FIG. 5.

As illustrated in FIG. 5, in an embodiment the display panel DP may include a scan driving circuit SDC, a plurality of signal lines SGL, and a plurality of pixels PX. The plurality of pixels PX are disposed in a display area DM-DA. Each of the pixels PX includes a light emitting element and a pixel driving circuit connected to the light emitting element. The scan driving circuit SDC, the plurality of signal lines SGL, and the pixel driving circuit may be included in the circuit layer DP-CL illustrated in FIG. 4.

The scan driving circuit SDC may include a gate driving circuit. The gate driving circuit generates a plurality of scan signals and sequentially outputs the plurality of scan signals to a plurality of scan lines GL to be described later. The scan driving circuit SDC may further include a light emission driving circuit separately from the gate driving circuit. The light emission driving circuit may output the scan signals to another group of scan signals.

In an embodiment, the scan driving circuit SDC may include a plurality of thin-film transistors formed through the same process as the pixel driving circuit, for example, a low temperature polycrystalline silicon (LTPS) process or a low temperature polycrystalline oxide (LTPO) process.

The plurality of signal lines SGL include the scan lines GL, data lines DL, a power line PL, and a control signal line CSL. Each of the scan lines GL is connected to a corresponding pixel PX among the plurality of pixels PX, and each of the data lines DL is connected to a corresponding pixel PX among the plurality of pixels PX. The power line PL is connected to the plurality of pixels PX. The data lines DL provide data signals to the pixels PX. The control signal line CSL may provide control signals to the scan driving circuit SDC.

The power line PL may be provided in plurality. For example, the power line PL may include a first power line which receives a first power voltage, and a second power line which receives a second power voltage having a higher level than the first power voltage. The first power voltage is provided to the pixel PX through the first power line, and the second power voltage is provided to the pixel PX through the second power line. Although one control signal line CSL is illustrated as an example in FIG. 5, the control signal line CSL may be provided in plurality in some embodiments.

The scan lines GL, the data lines DL, and the power line PL may overlap the display area DM-DA and a non-display area DM-NDA, and the control signal line CSL may overlap the non-display area DM-NDA. Respective ends of the plurality of signal lines SGL may be arranged on one side of the non-display area DM-NDA. For example, in an embodiment the respective ends of the plurality of signal lines SGL may be arranged on the lower side of the non-display area DM-NDA in the first direction DR1. However, embodiments of the present inventive concept are not necessarily limited thereto. In an embodiment, each of the plurality of signal lines SGL may have a shape of one body but may include a plurality of portions disposed on different layers from each other. Different portions divided by an insulating layer may be connected to each other through a contact hole passing through the insulating layer. For example, each of the data lines DL may include a first portion disposed in the display area DM-DA, and a second portion disposed in the non-display area DM-NDA and disposed on a different layer from the first portion. The first portion and the second portion may include different materials and have different stack structures from each other.

The plurality of signal lines SGL may be electrically connected, through a pad area PA, to the main circuit board MCB illustrated in FIG. 3.

A pixel driving circuit PC which drives a light emitting element LD may include a plurality of pixel driving elements. The pixel driving circuit PC may include a plurality of transistors S-TFT and O-TFT and a capacitor Cst. In an embodiment, the plurality of transistors S-TFT and O-TFT may include a silicon transistor S-TFT and an oxide transistor O-TFT. As an example, FIG. 6 illustrates the silicon transistor S-TFT and the oxide transistor O-TFT. However, the pixel driving circuit PC in FIG. 6 is just one embodiment, and the components of the pixel driver circuit PC are not necessarily limited thereto. The pixel driving circuit PC may include only one type of transistors among the silicon transistor S-TFT and the oxide transistor O-TFT.

Referring to FIG. 6, a base layer BL is illustrated as a single layer. The base layer BL may be a glass substrate, a metal substrate, a polymer substrate, or the like. However, embodiments of the present inventive concept are not necessarily limited thereto, and the base layer BL may be an inorganic layer, an organic layer, or a composite material layer.

A first shielding electrode (e.g., a shielding electrode) BML1may be disposed on the base layer BL (e.g., disposed directly thereon in the third direction DR3). The first shielding electrode BML1 may receive a bias voltage. The first shielding electrode BML1 may also receive the first power voltage. The first shielding electrode BML1 may prevent an electrical potential due to a polarization phenomenon from affecting the silicon transistor S-TFT. The first shielding electrode BML1 may prevent external light from reaching the silicon transistor S-TFT. In an embodiment of the present inventive concept, the first shielding electrode BML1 may be a floating electrode having a shape isolated from another electrode or line. The first shielding electrode BML1 may be arranged to correspond to the silicon transistor S-TFT. The first shield electrode BML1 may include a metal, for example, molybdenum.

A barrier layer BRL may be disposed on (e.g., disposed directly thereon) the base layer BL and the first shielding electrode BML1. The barrier layer BRL prevents foreign matter from being introduced from the outside. The barrier layer BRL may include at least one inorganic layer. In an embodiment, the barrier layer BRL may include a silicon oxide layer, a silicon nitride layer, or a silicon oxynitride layer. Each of these layers may be provided in plurality.

A buffer layer BFL may be disposed on (e.g., disposed directly thereon) the barrier layer BRL. The buffer layer BFL may prevent a phenomenon in which metal atoms or impurities spread from the base layer BL to a first semiconductor pattern SC1 above the buffer layer BFL. The buffer layer BFL may include at least one inorganic layer. For example, in an embodiment the buffer layer BFL may include a silicon oxide layer, a silicon nitride layer, or a silicon oxynitride layer.

The first semiconductor pattern SC1 may be disposed on the buffer layer BFL (e.g., disposed directly thereon in the third direction DR3). The first semiconductor pattern SC1 may include a silicon semiconductor. For example, in an embodiment the silicon semiconductor may include an amorphous silicon, a polycrystalline silicon, or the like. For example, the first semiconductor pattern SC1 may include low-temperature polysilicon.

The first semiconductor pattern SC1 may have different electrical properties according to whether the first semiconductor pattern SC1 is doped or not. The first semiconductor pattern SC1 may include a first region with high conductivity and a second region with low conductivity. The first region may be doped with an n-type dopant or a p-type dopant. A p-type transistor may include a doped region doped with the p-type dopant, and an n-type transistor may include a doped region doped with the n-type dopant. The second region may be a non-doped region, or a region doped at a lower concentration than the first region. In this embodiment, the first semiconductor pattern SC1 may be the n-type transistor.

The conductivity of the first region may be higher than the conductivity of the second region, and the first region may substantially serve as an electrode or a signal line. The second region may substantially correspond to a channel region (e.g., an active region) of a transistor. For example, one portion of the first semiconductor pattern SC1 may be a channel of a transistor, another portion thereof may be a source or drain of the transistor, and still another portion thereof may be a connection electrode or a connection signal line.

A source region SE1, a channel region AC1 (e.g., an active region), and a drain region DE1 of the silicon transistor S-TFT may be provided from the first semiconductor pattern SC1. The source region SE1 and the drain region DE1 may extend from the channel region AC1 in opposite directions on a cross-section.

A first insulating layer 10 may be disposed on (e.g., disposed directly thereon) the buffer layer BFL. The first insulating layer 10 may cover the first semiconductor pattern SC1. The first insulating layer 10 may be an inorganic layer. In an embodiment, the first insulating layer 10 may be a silicon oxide layer, a silicon nitride layer, or a silicon oxynitride layer. Not only the first insulating layer 10 but also an inorganic layer of the circuit layer DP-CL to be described later may have a single-layer structure or a multilayer structure, and may include at least one of the materials described above. However, embodiments of the present inventive concept are not necessarily limited thereto.

A gate (e.g., a gate electrode) GT1 of the silicon transistor S-TFT is disposed on the first insulating layer 10 (e.g., disposed directly thereon in the third direction DR3). The gate GT1 may be a portion of a metal pattern. The gate GT1 overlaps the channel region AC1 (e.g., in the third direction DR3). The gate GT1 may serve as a mask in a process of doping the first semiconductor pattern SC1. A first electrode CE10 of the storage capacitor Cst is disposed on the first insulating layer 10 (e.g., disposed directly thereon in the third direction DR3). Unlike an embodiment illustrated in FIG. 6, the first electrode CE10 may have a shape of one body together with the gate GT1.

A second insulating layer 20 may be disposed on (e.g., disposed directly thereon) the first insulating layer 10 and cover the gate GT1. In an embodiment of the present inventive concept, an upper electrode overlapping the gate GT1 may be further disposed on the second insulating layer 20. A second electrode CE20 overlapping the first electrode CE10 may be disposed on the second insulating layer 20 (e.g., disposed directly thereon in the third direction DR3). The upper electrode may have a shape of one body together with the second electrode CE20 on a plane.

A second shielding electrode BML2 is disposed on the second insulating layer 20 (e.g., disposed directly thereon in the third direction DR3). The second shielding electrode BML2 may be arranged to correspond to the oxide transistor O-TFT. In an embodiment of the present inventive concept, the second shielding electrode BML2 may be omitted. According to an embodiment of the present inventive concept, the first shielding electrode BML1 may extend to below the oxide transistor O-TFT and replace the second shielding electrode BML2.

A third insulating layer 30 may be disposed on (e.g., disposed directly thereon) the second insulating layer 20. A second semiconductor pattern SC2 may be disposed on the third insulating layer 30 (e.g., disposed directly thereon in the third direction DR3). The second semiconductor pattern SC2 may include a channel region AC2 of the oxide transistor O-TFT. The second semiconductor pattern SC2 may include a metal oxide semiconductor. In an embodiment, the second semiconductor pattern SC2 may include a transparent conductive oxide (TCO) such as indium tin oxide (ITO), indium zinc oxide (IZO), indium gallium zinc oxide (IGZO), zinc oxide (ZnOₓ), or indium oxide (In₂O₃).

The metal oxide semiconductor may include a plurality of regions SE2, AC2 and DE2 divided according to whether the transparent conductive oxide is reduced or not. A region in which the transparent conductive oxide is reduced (hereinafter referred to as a reduction region), has higher conductivity than a region in which the transparent conductive oxide is not reduced (hereinafter referred to as a non-reduction region). The reduction region substantially serves as a source/drain or a signal line of a transistor. The non-reduction region substantially corresponds to a semiconductor region (e.g., a channel region) of the transistor. For example, a partial region of the second semiconductor pattern SC2 may be the semiconductor region of the transistor, another partial region thereof may be a source region SE2/drain region DE2 of the transistor, and still another partial region thereof may be a signal transmitting region.

A fourth insulating layer 40 may be disposed on (e.g., disposed directly thereon) the third insulating layer 30. As illustrated in FIG. 6, the fourth insulating layer 40 may cover the second semiconductor pattern SC2. In an embodiment of the present inventive concept, the fourth insulating layer 40 may be an insulating pattern that overlaps a gate GT2 of the oxide transistor O-TFT and exposes each of the source region SE2 and the drain region DE2 of the oxide transistor O-TFT.

The gate GT2 of the oxide transistor O-TFT is disposed on the fourth insulating layer 40 (e.g., disposed directly thereon in the third direction DR3). The gate GT2 of the oxide transistor O-TFT may be a portion of a metal pattern. The gate GT2 of the oxide transistor O-TFT overlaps the channel region AC2 (e.g., in the third direction DR3).

A fifth insulating layer 50 may be disposed on (e.g., disposed directly thereon) the fourth insulating layer 40, and the fifth insulating layer 50 may cover the gate GT2. Each of the first insulating layer 10 to the fifth insulating layer 50 may be an inorganic layer. In an embodiment, each of the first insulating layer 10 to the fifth insulating layer 50 may be a silicon oxide layer, a silicon nitride layer, or a silicon oxynitride layer.

A conductive layer may be disposed on the fifth insulating layer 50 (e.g., disposed directly thereon in the third direction DR3). In an embodiment, the conductive layer may include a first connection pattern CNP1 and a second connection pattern CNP2. In an embodiment, the first connection pattern CNP1 and the second connection pattern CNP2 may be formed through the same process and thus have the same material and the same stack structure. In an embodiment, the first connection pattern CNP1 may be connected to (e.g., directly connected thereto) the drain region DE1 of the silicon transistor S-TFT through a first pixel contact hole PCH1 passing through the first to fifth insulating layers 10, 20, 30, 40 and 50. The second connection pattern CNP2 may be connected to (e.g., directly connected thereto) the source region SE2 of the oxide transistor O-TFT through a second pixel contact hole PCH2 passing through the fourth and fifth insulating layers 40 and 50. The connection relationships of the first connection pattern CNP1 and the second connection pattern CNP2 to the silicon transistor S-TFT and the oxide transistor O-TFT are not necessarily limited thereto.

A sixth insulating layer 60 may be disposed on (e.g., disposed directly thereon) the fifth insulating layer 50. A third connection pattern CNP3 may be disposed on the sixth insulating layer 60 (e.g., disposed directly thereon in the third direction DR3). In an embodiment, the third connection pattern CNP3 may be connected to (e.g., directly connected thereto) the first connection pattern CNP1 through a third pixel contact hole PCH3 passing through the sixth insulating layer 60. A data line DL may be disposed on the sixth insulating layer 60 (e.g., disposed directly thereon in the third direction DR3). A seventh insulating layer 70 may be disposed on the sixth insulating layer 60 (e.g., disposed directly thereon in the third direction DR3), and cover the third connection pattern CNP3 and the data line DL. In an embodiment, the third connection pattern CNP3 and the data line DL may be formed through the same process and thus have the same material and the same stack structure. Each of the sixth insulating layer 60 and the seventh insulating layer 70 may be an organic layer.

In an embodiment, the first shielding electrode BML1, the GT1 of the silicon transistor S-TFT, the second electrode CE20, and the gate GT2 of the oxide transistor O-TFT may include molybdenum (Mo), a molybdenum-containing alloy, titanium (Ti), or a titanium-containing alloy, each of which has good heat resistance. The first connection pattern CNP1 and the second connection pattern CNP2 may include aluminum having high electrical conductivity. The first connection pattern CNP1 and the second connection pattern CNP2 may each have a three-layer structure in which titanium/aluminum/titanium are stacked (e.g., in the third direction DR3).

The light emitting element LD may include an anode AE (e.g., a first electrode), a light emitting layer EL, and a cathode CE (e.g., a second electrode). The anode AE of the light emitting element LD may be disposed on the seventh insulating layer 70 (e.g., disposed directly thereon in the third direction DR3). The anode AE may be a transmissive electrode, a semi-transmissive electrode, or a reflective electrode. In an embodiment, the anode AE may include a stack structure of ITO/Ag/ITO stacked in sequence. The relative positions may be exchanged between the anode AE and the cathode CE in some embodiments.

A pixel defining film PDL may be disposed on the seventh insulating layer 70 (e.g., disposed directly thereon in the third direction DR3). The pixel defining film PDL may be an organic layer. The pixel defining film PDL may have a light absorbing property, and for example, the pixel defining film PDL may have a black color. The pixel defining film PDL may include a black component (e.g., a black coloring agent). The black component may include a black dye or a black pigment. In an embodiment, the black component may include a carbon black, a metal such as chrome, or an oxide thereof. The pixel defining film PDL may correspond to a light blocking pattern having a light blocking characteristic.

The pixel defining layer PDL may cover a portion of the anode AE. For example, an opening portion PDL-OP which exposes a portion of the anode AE may be defined in the pixel defining layer PDL. A light emitting area LA may be defined so as to correspond to the opening portion PDL-OP. In an embodiment of the present inventive concept, a hole control layer may be disposed between the anode AE and the light emitting layer EL (e.g., in the third direction DR3). The hole control layer may include a hole transport layer and further include a hole injection layer. An electron control layer may be disposed between the light emitting layer EL and the cathode CE (e.g., in the third direction DR3). The electron control layer may include an electron transport layer and further include an electron injection layer.

An encapsulation layer TFE may cover the light emitting element LD. In an embodiment, the encapsulation layer TFE may include a first insulating encapsulation layer IL1, a second insulating encapsulation layer IL2, and a third insulating encapsulation layer IL3. However, embodiments of the present inventive concept are not necessarily limited thereto, and the encapsulation layer TFE may further include a plurality of inorganic layers and organic layers.

The first insulating encapsulation layer IL1 may be an inorganic layer. The first insulating encapsulation layer IL1 may prevent outside moisture or oxygen from penetrating the light emitting element LD. For example, in an embodiment the first insulating encapsulation layer IL1 may include a silicon nitride, a silicon oxide, or a compound as a combination thereof. The first insulating encapsulation layer IL1 may be formed through a chemical vapor deposition process.

The second insulating encapsulation layer IL2 may be an organic layer. The second insulating encapsulation layer IL2 may be disposed on (e.g., disposed directly thereon) the first insulating encapsulation layer IL1 to be in direct contact with the first insulating encapsulation layer IL1. The second insulating encapsulation layer IL2 may provide a flat surface on the first insulating encapsulation layer IL1. An uneven portion on a top surface of the first insulating encapsulation layer IL1, particles present on the first insulating encapsulation layer IL1, or the like may be covered by the second insulating encapsulation layer IL2, thereby preventing a surface state of the top surface of the first insulating encapsulation layer IL1 from affecting components disposed on the second insulating encapsulation layer IL2. In addition, the second insulating encapsulation layer IL2 may reduce stress between layers that are in direct contact with each other. In an embodiment, the second insulating encapsulation layer IL2 may be formed through a solution process such as spin coating, slit coating, or inkjet process.

The third insulating encapsulation layer IL3 is disposed on (e.g., disposed directly thereon) the second insulating encapsulation layer IL2 to cover the second insulating encapsulation layer IL2. The third insulating encapsulation layer IL3 may be stably disposed on a relatively flat surface compared to an embodiment in which the third insulating encapsulation layer IL3 is disposed on the first insulating encapsulation layer IL1. The third insulating encapsulation layer IL3 may encapsulate moisture or the like discharged from the second insulating encapsulation layer IL2 and prevent the same from flowing to the outside.

The third insulating encapsulation layer IL3 may be an inorganic layer. In an embodiment, the third insulating encapsulation layer IL3 may include a silicon nitride, a silicon oxide, or a compound as a combination thereof. The third insulating encapsulation layer IL3 may be formed through a chemical vapor deposition process. Each of the first insulating encapsulation layer IL1, the second insulating encapsulation layer IL2, and the third insulating encapsulation layer IL3 may include a plurality of layers, and is not necessarily limited to any one embodiment.

An input sensing layer ISL may include at least one conductive layer (e.g., at least one sensor conductive layer) and at least one insulating layer (e.g., at least one sensor insulating layer). For example, in an embodiment, the input sensing layer ISL may include a first insulating layer IS-IL1, a first conductive layer ICL1, a second insulating layer IS-IL2, a second conductive layer ICL2, and a third insulating layer IS-IL3. A conductive line of the first conductive layer ICL1 and a conductive line of the second conductive layer ICL2 are illustrated in brief in FIG. 6.

The first insulating layer IS-IL1 may be directly disposed on the display panel DP. In an embodiment, the first insulating layer IS-IL1 may be an inorganic layer including at least one of silicon nitride, silicon oxynitride, or silicon oxide. Each of the first conductive layer ICL1 and the second conductive layer ICL2 may have a single-layer structure, or have a multilayer structure in which layers are stacked in the third direction DR3. The first conductive layer ICL1 and the second conductive layer ICL2 may include conductive lines which define a mesh-shaped electrode. In an embodiment, the conductive line of the first conductive layer ICL1 and the conductive line of the second conductive layer ICL2 may be connected to each other (e.g., directly connected to each other) through a contact hole passing through the second insulating layer IS-IL2 or may not be connected to each other. The connection relationship between the conductive line of the first conductive layer ICL1 and the conductive line of the second conductive layer ICL2 may be determined according to a type of sensor provided as the input sensing layer ISL.

The first conductive layer ICL1 and the second conductive layer ICL2, each of which has a single-layer structure, may include a metal layer or a transparent conductive layer. In an embodiment, the metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnOₓ), or indium zinc tin oxide (IZTO). In addition, the transparent conductive layer may include a conductive polymer such as PEDOT, metal nanowire, graphene, or the like.

In an embodiment, the first conductive layer ICL1 and the second conductive layer ICL2 may each include metal layers having a multilayer structure. The metal layers may have, for example, a three-layer structure of titanium/aluminum/titanium. The conductive layer having a multilayer structure may include at least one metal layer and at least one transparent conductive layer. The second insulating layer IS-IL2 may be disposed between the first conductive layer ICL1 and the second conductive layer ICL2 (e.g., in the third direction DR3). The third insulating layer IS-IL3 may cover the second conductive layer ICL2. In an embodiment of the present inventive concept, the third insulating layer IS-IL3 may be omitted. The second insulating layer IS-IL2 and the third insulating layer IS-IL3 may include an inorganic layer or an organic layer.

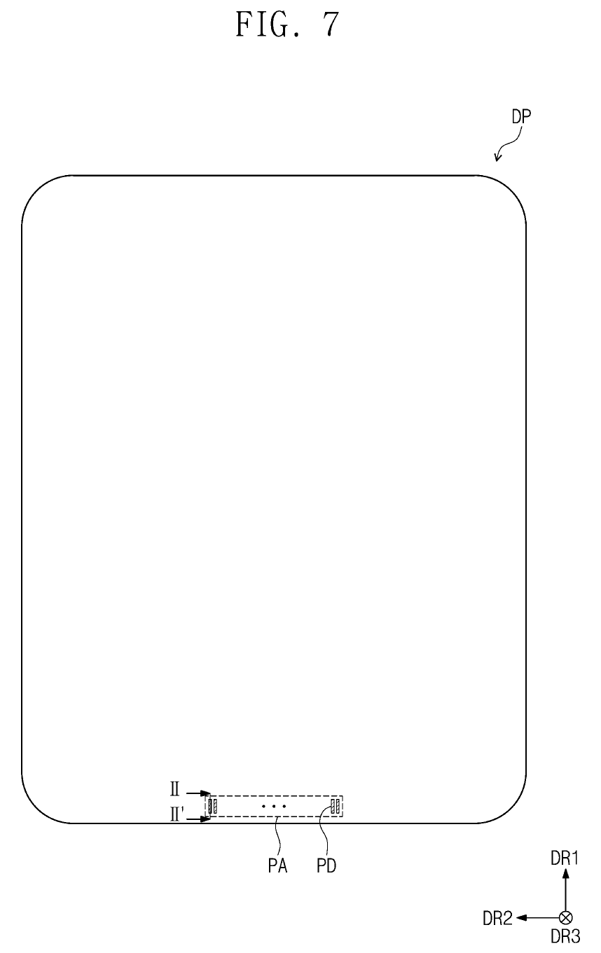

FIG. 7 is a plan view of a display panel DP according to an embodiment of the present inventive concept. Specifically, FIG. 7 is a rear view of the display panel DP when viewed in the third direction DR3.

Referring to FIG. 7, a pad electrode PD may be disposed on a rear surface of the display panel DP. In an embodiment, the pad electrode PD may be disposed in a pad area PA. In an embodiment, the pad electrode PD may be provided in plurality. The pad electrodes PD may be arranged in the second direction DR2.

The plurality of signal lines SGL (see FIG. 5) disposed in the display panel DP may be electrically connected, through the pad area PA, to the circuit board FCB illustrated in FIG. 3. For example, the plurality of signal lines SGL (see FIG. 5) may be disposed in the pad area PA and connected, through a connection electrode or the like, to the pad electrodes PD spaced apart from each other in the first direction DR1. The pad electrodes PD may be disposed on the rear surface of the display panel DP and electrically connected to the circuit board FCB (see FIG. 2).

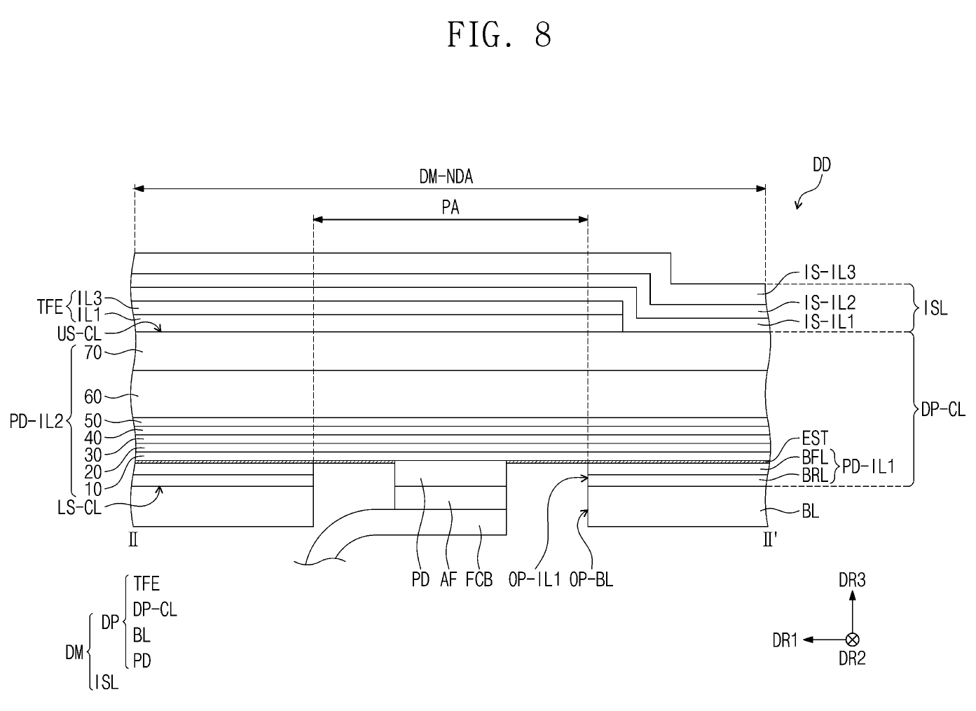

FIG. 8 is a cross-sectional view of a display device DD according to an embodiment of the present inventive concept. Specifically, FIG. 8 schematically illustrates a cross-section of the display device DD corresponding to line II-II' in FIG. 7. Hereinafter, the content overlapping with the content set forth above will be omitted for economy of explanation.

Referring to FIG. 8, the display device DD may include a display module DM and a circuit board FCB electrically connected to the display module DM. The display module DM may include a display panel DP. The display module DM may further include an input sensing layer ISL disposed on the display panel DP (e.g., disposed directly thereon in the third direction DR3).

The circuit board FCB may be disposed on a rear surface of the display panel DP and electrically connected to the display panel DP. In an embodiment, the circuit board FCB may be bonded, through an adhesive layer AF, to pad electrodes PD disposed in a pad area PA of the display panel DP and be electrically connected to the display panel DP. In an embodiment, the plurality of signal lines SGL (see FIG. 5) may be connected to the pad electrodes PD through a connection electrode or the like.

In an embodiment, the display panel DP may include a base layer BL, a circuit layer DP-CL disposed on the base layer BL, the light emitting element layer DP-ED (see FIG. 6) disposed on the circuit layer DP-CL, and an encapsulation layer TFE disposed on the light emitting element layer DP-ED (see FIG. 6). FIG. 8 illustrates a non-display area DM-NDA including the pad area PA, and the light emitting element layer DP-ED (see FIG. 6) is not disposed in the non-display area DM-NDA.

The base layer BS may be a glass substrate. Alternatively, the base layer BS may be a metal substrate, a polymer substrate, an inorganic layer, an organic layer, or a composite material layer. FIG. 8 illustrates the base layer BS having a single-layer structure, but the base layer BS may have a multilayer structure.

A base layer opening portion OP-BL overlapping the pad area PA may be defined in the base layer BL. The base layer opening portion OP-BL may completely pass through the base layer BL. For example, in an embodiment the base layer opening portion OP-BL may extend an entire thickness (e.g., in the third direction DR3) of the base layer BL. In an embodiment, the base layer opening portion OP-BL may be provided in plurality so as to correspond to the plurality of pad electrodes PD.

A portion of a bottom surface LS-CL of the circuit layer DP-CL may be exposed by the base layer opening portion OP-BL. Here, a top surface US-CL of the circuit layer DP-CL may be defined as a surface in direct contact with the light emitting element layer DP-ED (see FIG. 6) or the input sensing layer ISL. For example, the top surface US-CL of the circuit layer DP-CL may be in direct contact with the light emitting element layer DP-ED in the display area DM-DA (see FIG. 6) and be in direct contact with the input sensing layer ISL in the non-display area DM-NDA. The bottom surface LS-CL of the circuit layer DP-CL may be defined as a surface opposing the top surface US-CL (e.g., in the third direction DR3), such as a surface in direct contact with the base layer BL.

For backside bonding of the circuit board FCB, the pad electrodes PD may be disposed on the bottom surface LS-CL of the circuit layer DP-CL, which is exposed by the base layer opening portion OP-BL. The pad electrodes PD may be disposed inside the base layer opening portion OP-BL and exposed through the base layer opening portion OP-BL.

In an embodiment, the circuit layer DP-CL may include a first pad insulating layer PD-IL1 and a second pad insulating layer PD-IL2. Each of the first pad insulating layer PD-IL1 and the second pad insulating layer PD-IL2 may be at least one selected from the insulating layers BRL, BFL, 10, 20, 30, 40, 50, 60 and 70 included in the circuit layer DP-CL, described with reference to FIG. 6, and is defined to indicate insulating layers disposed in the pad area PA.

The circuit layer DP-CL may further include an etch stopper layer EST. The etch stopper layer EST may be arranged to extend from the display area DM-DA in FIG. 6, and is omitted in FIG. 6. FIG. 8 illustrates the etch stopper layer EST disposed directly below a first insulating layer 10 (e.g., in a direction opposite to the third direction DR3), but the position of the etch stopper layer EST is not necessarily limited thereto and may be changed within the circuit layer DP-CL. The etch stopper layer EST may be a layer including a material having an etching selectivity which may be protected against an etchant capable of removing the base layer BL and the first pad insulating layer PD-IL1. For example, in an embodiment the etch stopper layer EST may include amorphous silicon (a-Si), silicon nitride (SiNₓ), or polyimide (PI).

The first pad insulating layer PD-IL1 may be defined as insulating layers in which an opening portion corresponding to the base layer opening portion OP-BL is defined. For example, in FIG. 8, the first pad insulating layer PD-IL1 may correspond to a barrier layer BRL and a buffer layer BFL. The opening portion defined in the first pad insulating layer PD-IL1 may be referred to as a first pad insulating layer opening portion OP-IL1. The first pad insulating layer PD-IL1 may be disposed below the etch stopper layer EST (e.g., directly therebelow in a direction opposite to the third direction DR3). As used herein, an upward direction may be a direction in which the third direction DR3 points, and a downward direction may be an opposite direction to the direction in which the third direction DR3 points. In an embodiment, an etchant, which allows the base layer BL and the first pad insulating layer PD-IL1 to be removed and the etch stopper layer EST and the pad electrode PD to remain, may be used in a wet etching process for forming the base layer opening portion OP-BL and the first pad insulating layer opening portion OP-IL1. Thus, a portion of the etch stopper layer EST and the pad electrode PD may be exposed by the first pad insulating layer opening portion OP-IL1.

The second pad insulating layer PD-IL2 may be defined as insulating layers in which an opening portion is not defined. For example, in FIG. 8, the second pad insulating layer PD-IL2 may correspond to first to seventh insulating layers 10, 20, 30, 40, 50, 60 and 70. The second pad insulating layer PD-IL2 may be disposed above the etch stopper layer EST (e.g., in the third direction DR3). The etchant, which allows the base layer BL and the first pad insulating layer PD-IL1 to be removed and the etch stopper layer EST and the pad electrode PD to remain, may be used in the foregoing wet etching process for forming the base layer opening portion OP-BL and the first pad insulating layer opening portion OP-IL1. Thus, the second pad insulating layer PD-IL2 disposed above the etch stopper layer EST and the pad electrode PD may remain without being removed in the wet etching process for forming the base layer opening portion OP-BL and the first pad insulating layer opening portion OP-IL1.

In the display device DD according to an embodiment of the present inventive concept, the circuit board FCB may be backside bonded to the display panel DP, thereby achieving the non-display area DM-NDA having a relatively small surface area. Moreover, the circuit board FCB may be coupled through the pad electrodes PD disposed on the bottom surface LS-CL of the circuit layer DP-CL, thereby making the display device DD relatively thin.

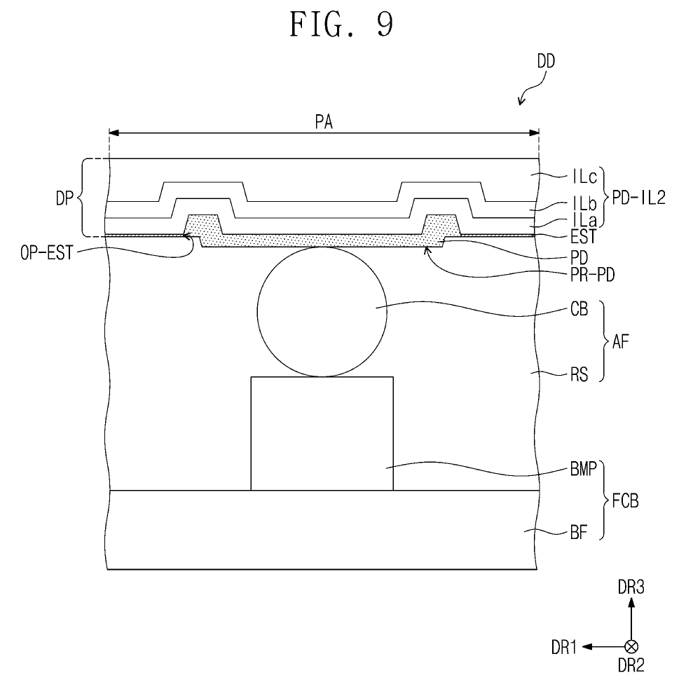

FIG. 9 is an enlarged cross-sectional view of a portion of a display device DD according to an embodiment of the present inventive concept. Specifically, FIG. 9 is an enlarged cross-sectional view of a portion at which a display panel DP and a circuit board FCB are connected in the pad area PA in FIG. 8. The pad area PA in FIG. 9 is illustrated on the basis of a pad electrode PD disposed inside the base layer opening portion OP-BL (see FIG. 8) and the first pad insulating layer opening portion OP-IL1 (see FIG. 8). In addition, for convenience of explanation, three insulating layers ILa, ILb and ILc are illustrated as representative of the insulating layers 10, 20, 30, 40, 50, 60 and 70 (see FIG. 8) included in a second pad insulating layer PD-IL2.

Referring to FIG. 9, the pad electrode PD may be disposed below the second pad insulating layer PD-IL2 (e.g., directly below in a direction opposite to the third direction DR3). An etch stopper layer opening portion OP-EST which exposes the pad electrode PD may be defined in an etch stopper layer EST. The pad electrode PD may include a protrusion PR-PD protruding in a direction from a light emitting element layer DP-ED towards a circuit layer DP-CL (e.g., in a direction opposite to the third direction DR3). In an embodiment, a thickness (e.g., length in the third direction DR3) of the protrusion PR-PD may be the same as a thickness (e.g., length in the third direction DR3) of a first pad insulating layer PD-IL1 having been removed in a wet etching process for forming the base layer opening portion OP-BL (see FIG. 8) and the first pad insulating layer opening portion OP-IL1 (see FIG. 8), which will be described later. Here, the thickness of the protrusion PR-PD may mean a length from the etch stopper layer EST to the most protruding portion of the pad electrode PD in the third direction DR3.

The second pad insulating layer PD-IL2 may include at least one inorganic layer and may include at least one organic layer. For example, in an embodiment a first layer ILa and a second layer ILb may each be an inorganic layer, and a third layer ILc may be an organic layer. For example, in an embodiment the second pad insulating layer PD-IL2 may include at least one organic layer and at least one inorganic layer disposed below the at least one organic layer.

The circuit board FCB may include a base film BF, and a bump electrode BMP disposed on the base film BF and overlapping the pad electrode PD on a plane. In an embodiment, the base film BF may be electrically connected to the bump electrode BMP provided in plurality. In this embodiment, a plurality of lines may be included inside the base film BF. In an embodiment, the base film BF may include a synthetic resin material, for example, polyimide. The bump electrodes BMP may be disposed on the base film BF (e.g., disposed directly thereon in the third direction DR3).

An adhesive layer AF may be disposed between the base film BF and the pad electrode PD (e.g., in the third direction DR3). The adhesive layer AF may be disposed between the display panel DP and the circuit board FCB (e.g., in the third direction DR3) and connect the display panel DP to the circuit board FCB. The adhesive layer AF may include an adhesive resin RS and conductive particles CB dispersed in the adhesive resin RS. The adhesive resin RS may be filled in a space between the conductive particles CB and couple the display panel DP to the circuit board FCB.

The adhesive resin RS may include a polymer material. For example, in an embodiment the adhesive resin RS may include at least one of an acrylic polymer, a silicon-based polymer, a urethane-based polymer, or an imide-based polymer. In an embodiment, the adhesive resin RS may be a portion formed by heat curing or photocuring a base resin such as acrylic resin, silicon-based resin, urethane-based resin, or imide-based resin. The adhesive resin RS may be a non-conductive film.

The conductive particles CB may be metal particles, alloy particles in which a plurality of metals are mixed, or the like. For example, in an embodiment the conductive particles CB may be metal or metal alloy particles including at least one of silver, copper, bismuth, zinc, indium, tin, nickel, cobalt, chrome, or iron. Alternatively. the conductive particles CB may each have a core portion including a polymer resin or the like, and a coating layer surrounding the core portion and including a conductive material.

In an embodiment, the conductive particles CB may be aligned between the pad electrode PD and the bump electrode BMP of the circuit board FCB, corresponding to each other, through pressing during the bonding of the circuit board FCB, and have anisotropy such that a current flows in the pressing direction. Accordingly, the pad electrode PD of the display panel DP may be electrically connected to the circuit board FCB through the conductive particles MB. FIG. 9 illustrates the conductive particle CB which is not embedded but in direct contact with the pad electrode PD and the bump electrode BMP, but the conductive particle CB may come into direct contact as being partially embedded in the pad electrode PD and the bump electrode BMP by pressing. Alternatively, the conductive particle CB may include a core metal and a low-melting point conductive material surrounding the core metal, and the low-melting point conductive material may come into direct contact with the pad electrode PD and the bump electrode BMP during a pressing process.

In the display device DD (see FIG. 8) according to an embodiment of the present inventive concept, as the pad electrode PD includes the protrusion PR-PD, a stepped portion caused by a tolerance of the bump electrode BMP may be compensated, and the embedding degree of the conductive particle CB may be increased compared to a case in which the protrusion PR-PD is not included. Accordingly, contact resistance may be reduced. In addition, as the protrusion PR-PD is included, slips during the bonding process of the display panel DP and the circuit board FCB may be prevented.

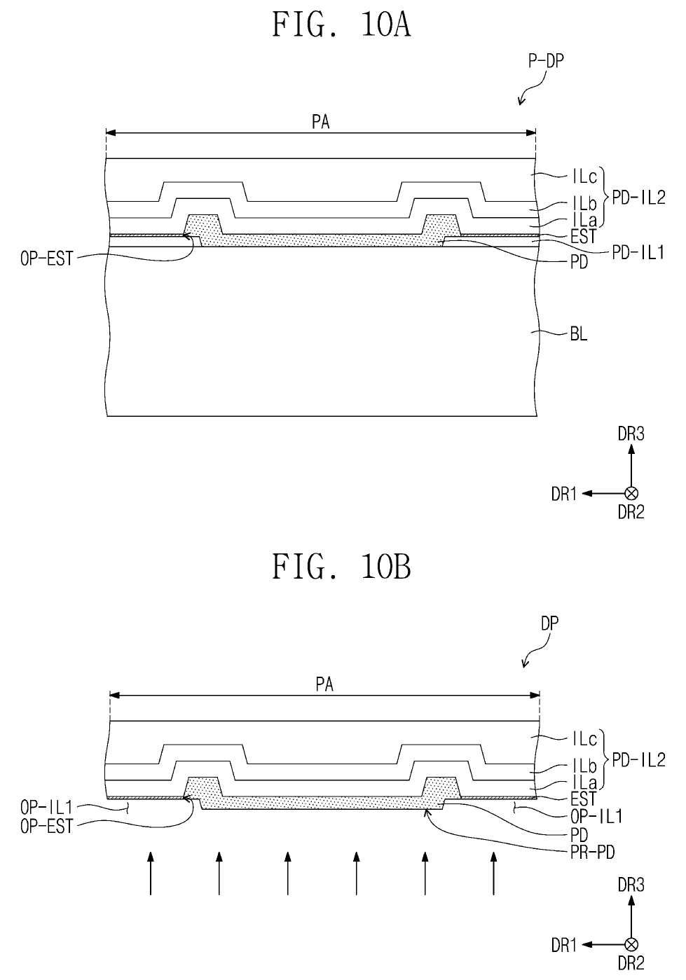

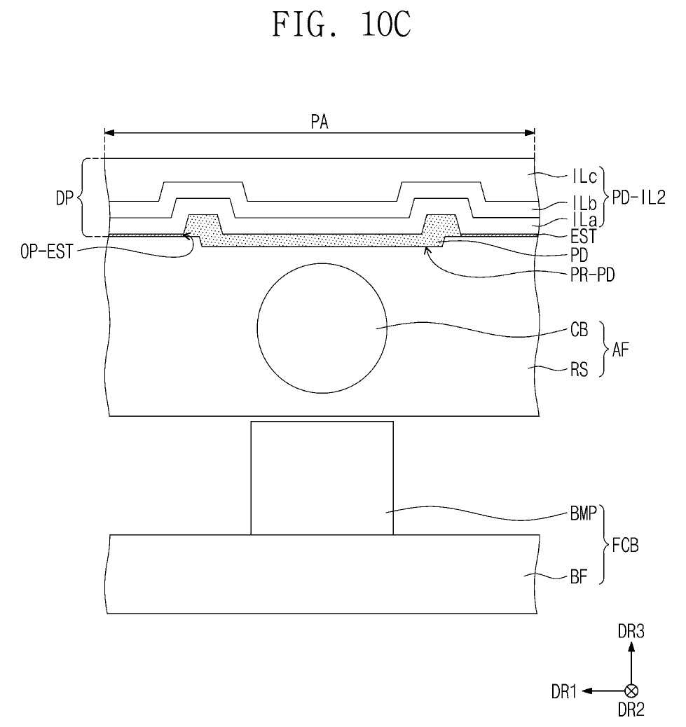

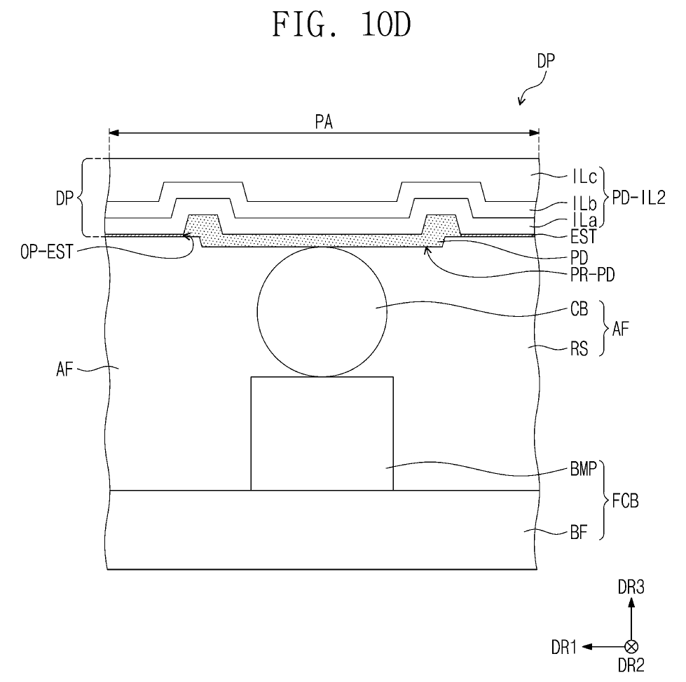

FIGS. 10A to 10D are each a cross-sectional view illustrating one step of a method for manufacturing a display device DD according to embodiments of the present inventive concept. Specifically, FIGS. 10A to 10D illustrate a pad area PA corresponding to FIG. 9.

The method for manufacturing the display device DD according to an embodiment of the present inventive concept may include providing a preliminary display panel P-DP, forming a base layer opening portion OP-BL and a first pad insulating layer opening portion OP-IL1, and bonding a display panel DP to a circuit board FCB.

FIG. 10A illustrates the providing of the preliminary display panel P-DP. Referring to FIG. 10A, in an embodiment the preliminary display panel P-DP may include a base layer BL, a first pad insulating layer PD-IL1 disposed on the base layer BL (e.g., disposed directly thereon in the third direction DR3), an etch stopper layer EST disposed on the first pad insulating layer PD-IL1 (e.g., disposed directly thereon in the third direction DR3), and a second pad insulating layer PD-IL2 disposed on the etch stopper layer EST (e.g., disposed directly thereon in the third direction DR3). As an example, FIG. 10A illustrates the second pad insulating layer PD-IL2 which includes two inorganic layers ILa and ILb and one organic layer ILc.

The first pad insulating layer PD-IL1 may be formed on the base layer BL (e.g., formed directly thereon in the third direction DR3). In an embodiment, the first pad insulating layer PD-IL1 may include at least one inorganic layer. In some embodiments, the first pad insulating layer PD-IL1 may further include at least one organic layer disposed on (e.g., disposed above) the at least one inorganic layer. In an embodiment, the first pad insulating layer PD-IL1 may be patterned to include an opening portion at a position for disposing a pad electrode PD. The pad electrode PD may be formed on the base layer BL (e.g., formed directly thereon in the third direction DR3). The pad electrode PD may be formed while covering a portion of the first pad insulating layer PD-IL1, such as lateral ends of the first pad insulating layer PD-IL1 adjacent the opening. Thereafter, the etch stopper layer EST and the second pad insulating layer PD-IL2 may be formed on the first pad insulating layer PD-IL1. The etch stopper layer EST may include an etch stopper layer opening portion OP-EST corresponding to the pad electrode PD. For example, since the pad electrode PD is formed prior to the forming of the etch stopper layer EST, the etch stopper layer opening portion OP-EST may be formed to correspond to the positioning of the pad electrode PD. In an embodiment, the etch stopper layer EST may be formed in a process of forming inorganic films of the first pad insulating layer PD-IL1 and the second pad insulating layer PD-IL2. The position of the etch stopper layer EST may be changed.

FIG. 10B illustrates the forming of the base layer opening portion OP-BL (see FIG. 8) and the first pad insulating layer opening portion OP-IL1 (see FIG. 8). In an embodiment, the base layer BL of the pad area PA may be grooved to a certain depth by using a grinding wheel. Thereafter, the remaining base layer BL of the pad area PA may be etched through a wet etching process to form the base layer opening portion OP-BL (see FIG. 8). In the same wet etching process, the first pad insulating layer opening portion OP-IL1 of the pad area PA may be also etched to form the first pad insulating layer opening portion OP-IL1 (see FIG. 8). An etchant may allow the base layer BL and the first pad insulating layer PD-IL1 to be removed but the pad electrode PD and the etch stopper layer EST to remain. Accordingly, the pad electrode PD may be exposed by protruding as much as a thickness of the removed first pad insulating layer IPD-IL1 (e.g., in a direction opposite to the third direction DR3).

FIGS. 10C and 10D may illustrate the bonding of the display panel DP to the circuit board FCB. In an embodiment, an adhesive layer AF may be disposed between the display panel DP and the circuit board FCB (e.g., in the third direction DR3), and the display panel DP and the circuit board FCB may be bonded to each other by pressing. The pad electrode PD and a bump electrode BMP may be arranged to correspond to each other. During the bonding process, the bump electrode BMP of the circuit board FCB may be electrically connected to the pad electrode PD of the display panel DP through conductive particles CB.

In the method for manufacturing the display device DD (see FIG. 8) according to an embodiment of the present inventive concept, as the etch stopper layer EST is disposed between the insulating layers PD-IL1 and PD-IL2 (e.g., in the third direction DR3) in the circuit layer DP-CL (see FIG. 8) of the display panel DP, the insulating layer PD-IL1 disposed below the etch stopper layer EST may be removed together in the wet etching process for forming the base layer opening portion OP-BL (see FIG. 8). Accordingly, the pad electrode PD may include a protrusion PR-PD (e.g., in a direction opposite to the third direction DR3) and have a structure from which the protrusion PR-PD is exposed. As the pad electrode PD includes the protrusion PR-PD, in a subsequent bonding process of the display panel DP and the circuit board FCB, a stepped portion caused by a tolerance of the bump electrode BMP may be compensated, and the embedding degree of the conductive particle CB may be increased in contrast to a comparative embodiment in which the protrusion PR-PD is not included. Accordingly, contact resistance may be reduced. In addition, as the protrusion PR-PD is included, slips during the bonding process of the display panel DP and the circuit board FCB may be prevented.

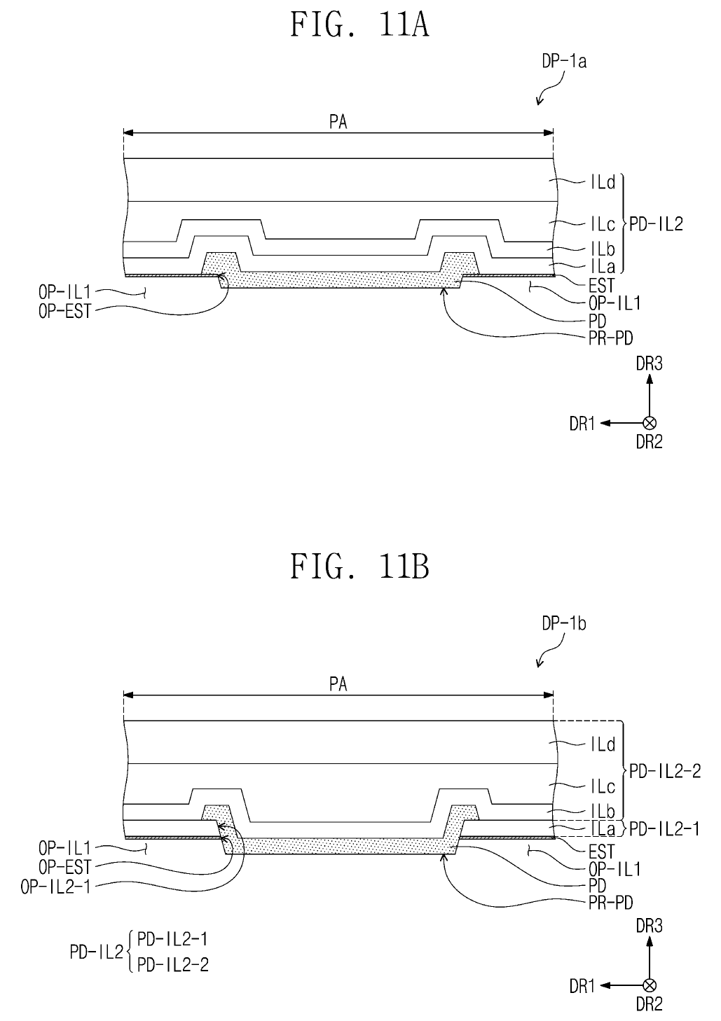

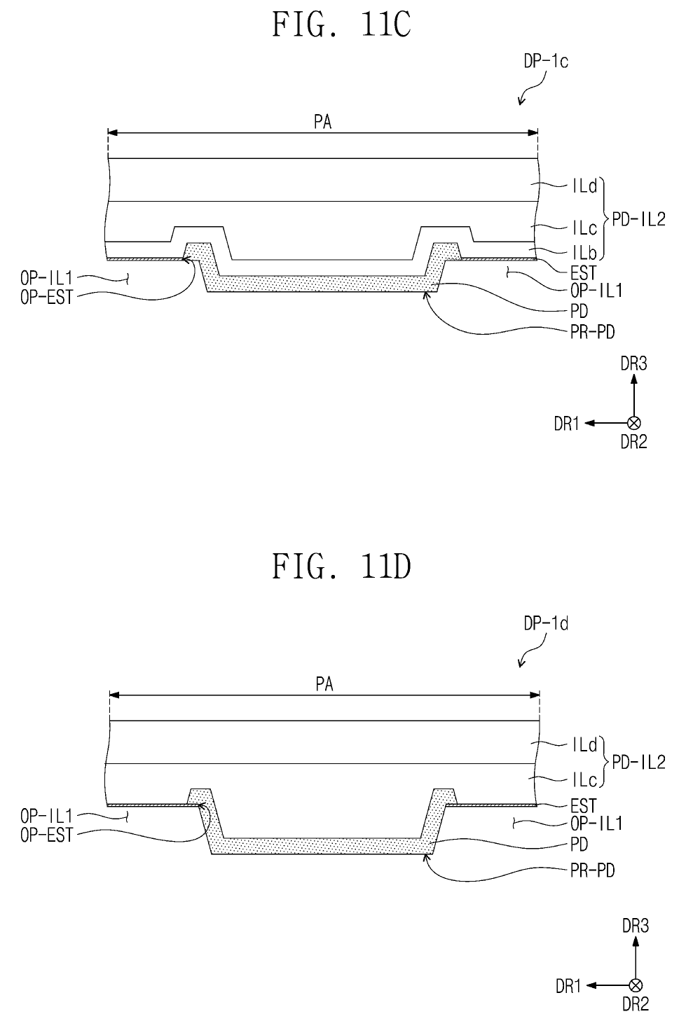

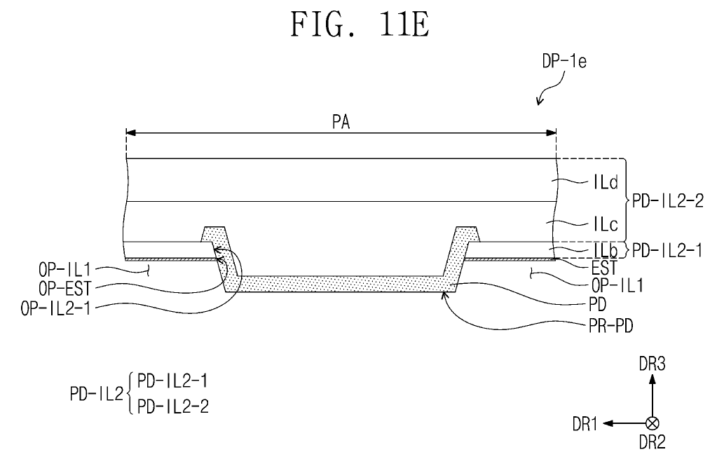

FIGS. 11A to 16J are each an enlarged cross-sectional view of a portion of a display panel according to embodiments of the present inventive concept. Specifically, like FIG. 9, FIGS. 11A to 16J are enlarged cross-sectional views of other embodiments of the pad area PA in FIG. 8.

In FIGS. 11A to 16J like FIG. 9, the pad area PA is illustrated on the basis of a pad electrode PD disposed inside the base layer opening portion OP-BL (see FIG. 8) and the first pad insulating layer opening portion OP-IL1 (see FIG. 8). FIGS. 11A to 16J illustrate the inside of the base layer opening portion OP-BL (see FIG. 8), and the reference symbol of the base layer opening portion OP-BL (see FIG. 8) is omitted. In addition, for convenience of explanation, first to fourth layers ILa, ILb, ILc and ILd are illustrated as representative of the insulating layers 10, 20, 30, 40, 50, 60 and 70 (see FIG. 8) included in a second pad insulating layer PD-IL2. In addition, in an embodiment the first layer ILa and the second layer ILb may be representative of inorganic layers, and the third layer ILc and the fourth layer ILd may be representative of organic layers.

Referring to FIG. 11A, a display panel DP-1a according to an embodiment may have a structure in which a pad electrode PD is formed later than an etch stopper layer EST. For example, the etch stopper layer EST may be formed earlier than the pad electrode PD, and the pad electrode PD may be formed on (e.g., formed directly thereon) the etch stopper layer EST. A protrusion PR-PD of the pad electrode PD may be exposed by an opening portion OP-EST defined in the etch stopper layer EST. For example, in an embodiment the opening portion OP-EST of the etch stopper layer may be formed during an etching process. A non-protrusion portion of the pad electrode PD may be overlapped by the etch stopper layer EST (e.g., in a direction opposite to the third direction DR3).

Referring to FIG. 11B, a second pad insulating layer PD-IL2 of a display panel DP-1b according to an embodiment may include a (2-1)-th pad insulating layer PD-IL2-1 in which an opening portion OP-IL2-1 which exposes a pad electrode PD is defined, and a (2-2)-th pad insulating layer PD-IL2-2 in which an opening portion is not defined. The (2-1)-th pad insulating layer PD-IL2-1 may include a (2-1)-th pad insulating layer opening portion OP-IL2-1 corresponding to (e.g., overlapping in a plan view) an etch stopper layer opening portion OP-EST, which exposes the pad electrode PD, and be disposed on the etch stopper layer EST (e.g., disposed directly thereon in the third direction DR3). For example, in an embodiment the edges of the first pad insulating layer formed by the opening portion of the first pad insulating layer OP-IL1, the edges of the etch stopper layer EST formed by the opening portion OP-EST of the etch stopper layer and the edges of the (2-1)-th pad insulating layer PD-IL2-1 formed by the (2-1)-th pad insulating layer opening portion OP-IL2-1 may be aligned with each other. The pad electrode PD may have a structure in which the pad electrode PD is formed later than the etch stopper layer EST and the (2-1)-th pad insulating layer PD-IL2-1.

Referring to FIGS. 11C to 11E, a pad electrode PD of a display panel DP-1c, DP-1d or DP-1e according to an embodiment may have a further protruding structure (e.g., in a direction opposite to the third direction DR3) than the pad electrode PD of the display panel DP in FIG. 9. Insulating layers disposed below an etch stopper layer EST may be removed in the wet etching process described above with reference to FIG. 10B. Thus, like FIGS. 11C to 11E, a position of the etch stopper layer EST may be adjusted to adjust the insulating layers to be removed in the wet etching process.

In an embodiment shown in FIG. 11C, the etch stopper layer EST may be disposed below a second layer ILb (e.g., directly therebelow in a direction opposite to the third direction DR3). In this embodiment, unlike FIG. 9, the first layer ILa (see FIG. 9) may be included in the first pad insulating layer PD-IL1 (see FIG. 8) which defines a first pad insulating layer opening portion OP-IL1. The display panel DP-1c in FIG. 11C may have a structure in which the first layer ILa and the etch stopper layer EST on the first layer ILa are formed and then the pad electrode PD is formed.

In an embodiment shown in FIG. 11D, the etch stopper layer EST may be disposed below a third layer ILc (e.g., disposed directly therebelow in a direction opposite to the third direction DR3). In this embodiment, unlike FIG. 9, the first layer ILa (see FIG. 9) and the second layer ILb (see FIG. 9) may be included in the first pad insulating layer PD-IL1 (see FIG. 8) which defines a first pad insulating layer opening portion OP-IL1. The display panel DP-1d in FIG. 11D may have a structure in which the first layer ILa (see FIG. 9), the second layer ILb (see FIG. 9) on the first layer ILa (see FIG. 9), and the etch stopper layer EST on the second layer ILb (see FIG. 9) are formed and then the pad electrode PD is formed.

In an embodiment shown in FIG. 11E, like FIG. 11C, the etch stopper layer EST may be disposed below the second layer ILb (e.g., directly therebelow in a direction opposite to the third direction DR3), and the first layer ILa (see FIG. 9) may be included in the first pad insulating layer PD-IL1 (see FIG. 8) which defines a first pad insulating layer opening portion OP-IL1. In the display panel DP-1e in FIG. 11E, at least one insulating layer included in a second pad insulating layer PD-IL2 disposed on the etch stopper layer EST may include an opening portion which exposes the pad electrode PD. In an embodiment, the second pad insulating layer PD-IL2 may include a (2-1)-th pad insulating layer PD-IL2-1 and a (2-2)-th pad insulating layer PD-IL2-2. The (2-1)-th pad insulating layer PD-IL2-1 may be disposed on the etch stopper layer EST (e.g., disposed directly thereon in the third direction DR3) and include a (2-1)-th pad insulating layer opening portion OP-IL2-1 which exposes the pad electrode PD. The (2-1)-th pad insulating layer opening portion OP-IL2-1 may correspond to (e.g., overlap in the third direction DR3) an etch stopper layer opening portion OP-EST. For example, the second layer ILb may be included in the (2-1)-th pad insulating layer PD-IL2-1 including the (2-1)-th pad insulating layer opening portion OP-IL2-1. In addition, the third layer ILc and the fourth layer ILd may be included in the (2-2)-th pad insulating layer PD-IL2-2 which does not include an opening portion.

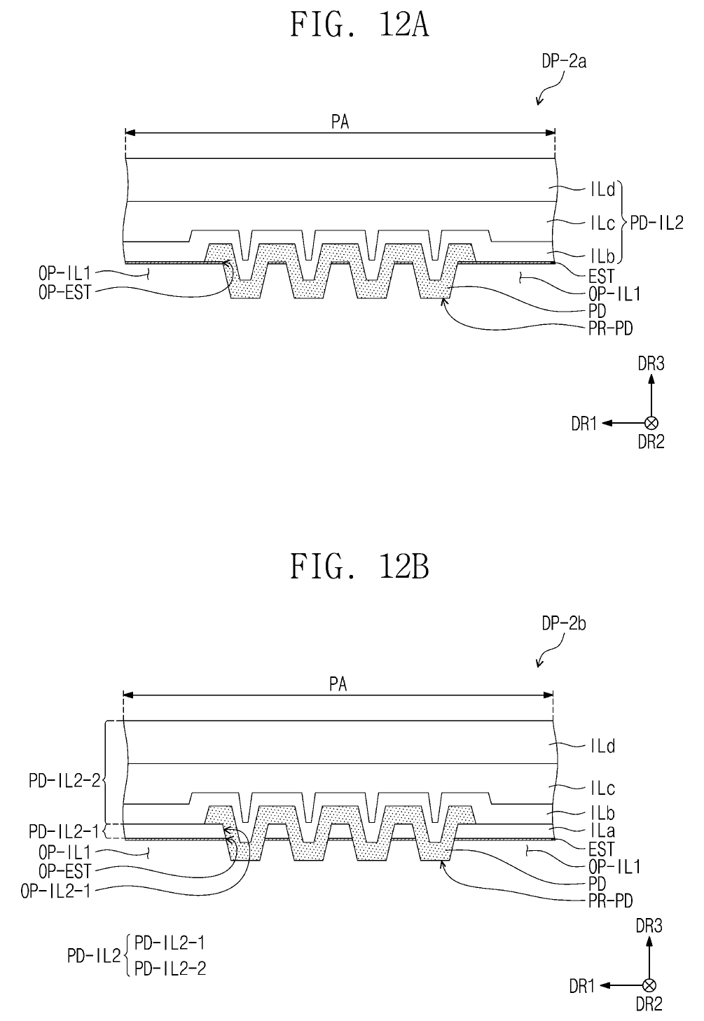

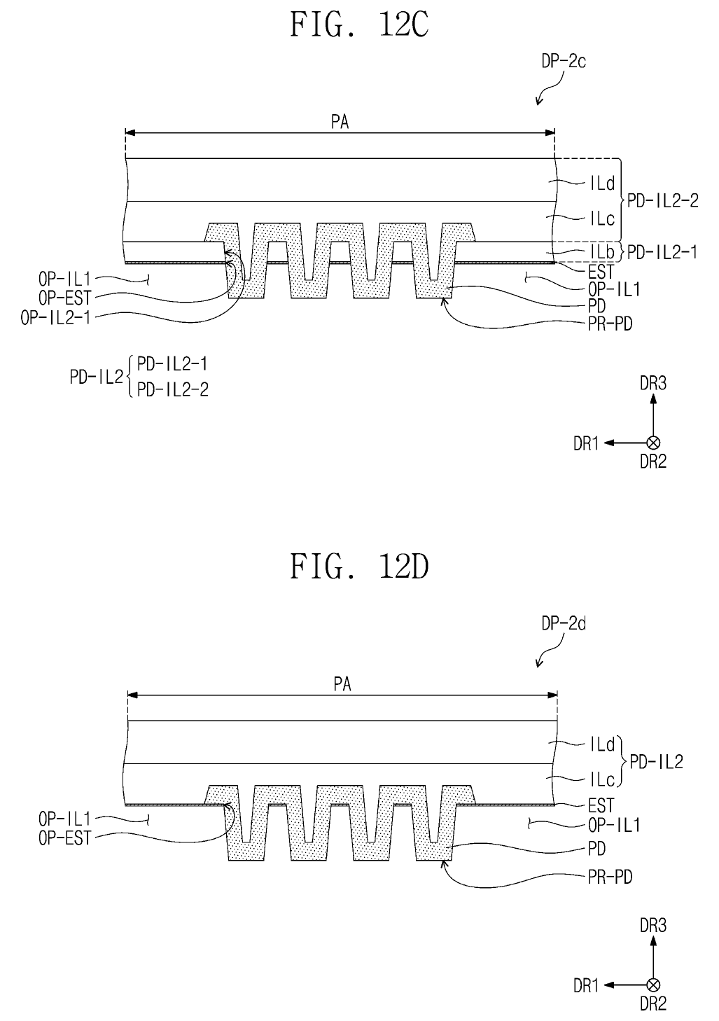

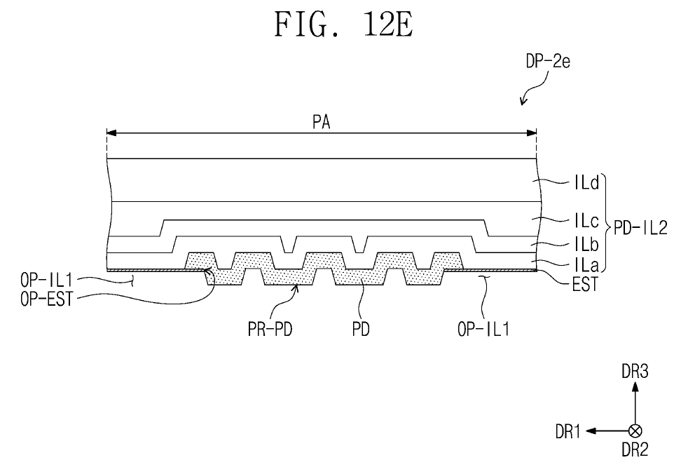

Referring to FIGS. 12A to 12E, a pad electrode PD of a display panel DP-2a, DP-2b, DP-2c, DP-2d or DP-2e according to an embodiment may include a plurality of protrusions PR-PD in which each of the plurality of protrusions PR-PD protrude in a direction opposite to the third direction DR3. As an example, FIGS. 12A to 12E each illustrate a structure including four protrusions PR-PD when viewed on a cross-section, but the number of the protrusions PR-PD is not necessarily limited thereto and may vary. When the pad electrode PD includes the plurality of protrusions PR-PD, a surface area of the pad electrode PD with which the conductive particles CB (see FIG. 9) may come into direct contact may be increased, thereby increasing the adhesion and further reducing the contact resistance.

In FIG. 12A, like FIG. 11C, an etch stopper layer EST may be disposed below a second layer ILb (e.g., directly therebelow in a direction opposite to the third direction DR3), and the first layer ILa (see FIG. 9) may be included in the first pad insulating layer PD-IL1 (see FIG. 8) which defines a first pad insulating layer opening portion OP-IL1. The display panel DP-2a in FIG. 12A may have a structure in which the etch stopper layer EST is formed and then the pad electrode PD is formed (e.g., formed directly thereon).

In an embodiment shown in FIG. 12B, like FIG. 11B, a second pad insulating layer PD-IL2 may include a (2-1)-th pad insulating layer PD-IL2-1 in which an opening portion OP-IL2-1 which exposes the pad electrode PD is defined, and a (2-2)-th pad insulating layer PD-IL2-2 in which an opening portion is not defined. In an embodiment, the (2-1)-th pad insulating layer PD-IL2-1 may include a (2-1)-th pad insulating layer opening portion OP-IL2-1 corresponding to (e.g., overlapping in the third direction DR3) an etch stopper layer opening portion OP-EST, which exposes the pad electrode PD, and be disposed on the etch stopper layer EST (e.g., disposed directly thereon in the third direction DR3). A structure may be provided in which the pad electrode PD is formed later than the etch stopper layer EST and the (2-1)-th pad insulating layer PD-IL2-1.

In an embodiment shown in FIG. 12C, like FIG. 11E, an etch stopper layer EST may be disposed below a second layer ILb (e.g., directly therebelow in a direction opposite to the third direction DR3), and the first layer ILa (see FIG. 9) may be included in the first pad insulating layer PD-IL1 (see FIG. 8) which defines a first pad insulating layer opening portion OP-IL1. At least one insulating layer included in a second pad insulating layer PD-IL2 disposed on the etch stopper layer EST may include an opening portion which exposes the pad electrode PD. In an embodiment, the second pad insulating layer PD-IL2 may include a (2-1)-th pad insulating layer PD-IL2-1 and a (2-2)-th pad insulating layer PD-IL2-2. The (2-1)-th pad insulating layer PD-IL2-1 may be disposed on the etch stopper layer EST (e.g., disposed directly thereon in the third direction DR3) and include a (2-1)-th pad insulating layer opening portion OP-IL2-1 which exposes the pad electrode PD. The (2-1)-th pad insulating layer opening portion OP-IL2-1 may correspond to (e.g., overlap in the third direction DR3) an etch stopper layer opening portion OP-EST. For example, the second layer ILb may be included in the (2-1)-th pad insulating layer PD-IL2-1 including the (2-1)-th pad insulating layer opening portion OP-IL2-1. In addition, a third layer ILc and a fourth layer ILd may be included in the (2-2)-th pad insulating layer PD-IL2-2 which does not include an opening portion.

In an embodiment shown in FIG. 12D, like FIG. 11D, an etch stopper layer EST may be disposed below a third layer ILc (e.g., disposed directly therebelow in the third direction DR3), and the first layer ILa (see FIG. 9) and the second layer ILb (see FIG. 9) may be included in the first pad insulating layer PD-IL1 (see FIG. 8) which defines a first pad insulating layer opening portion OP-IL1. A structure may be provided in which the first layer ILa (see FIG. 9), the second layer ILb (see FIG. 9) on the first layer ILa (see FIG. 9), and the etch stopper layer EST on the second layer ILb (see FIG. 9) are formed and then the pad electrode PD is formed.

In an embodiment shown in FIG. 12E, like FIG. 11A, a structure may be provided in which the pad electrode PD is formed later than an etch stopper layer EST. For example, the etch stopper layer EST may be formed earlier than the pad electrode PD, and the pad electrode PD may be formed on the etch stopper layer EST (e.g., formed directly thereon in the third direction DR3). The protrusions PR-PD of the pad electrode PD may be exposed by an opening portion OP-EST defined in the etch stopper layer EST. At least a portion of a non-protrusion portion of the pad electrode PD may be overlapped by the etch stopper layer EST (e.g., in a direction opposite to the third direction DR3). In addition, a remaining portion, which is not covered by the etch stopper layer EST, of the non-protrusion portion of the pad electrode PD may be exposed by the etch stopper layer EST. In the display panel DP-2e in FIG. 12E, at least one insulating layer may be patterned on a base layer BL so as to have an opening portion at a position on which the protrusions PR-PD of the pad electrode PD is formed. The pad electrode PD may be formed on the patterned insulating layer. Then, the etch stopper layer EST and a second pad insulating layer PD-IL2 may be formed on the pad electrode PD, and a wet etching process may be performed to form the display panel DP-2e.

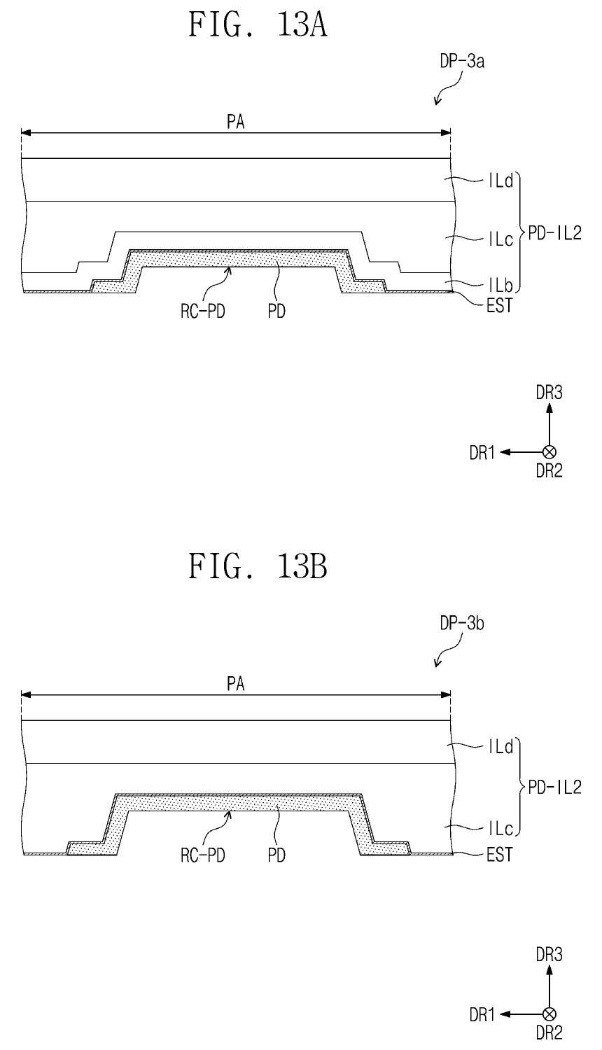

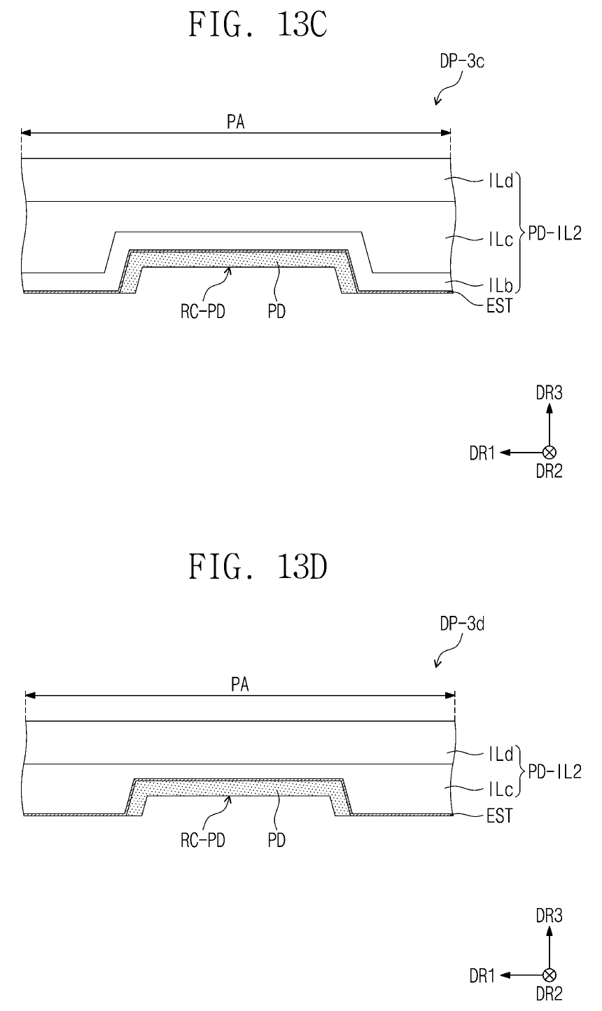

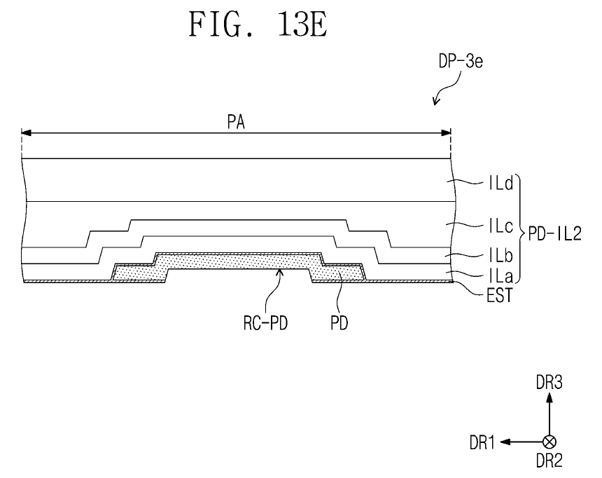

Referring to FIGS. 13A to 13E, a pad electrode PD of a display panel DP-13a, DP-13b, DP-13c, DP-13d or DP-13e according to an embodiment may include a recess RC-PD. The recess RC-PD may be recessed in a direction from the circuit layer DP-CL (see FIG. 8) towards a light emitting element layer DP-ED (e.g., in the third direction DR3). As the pad electrode PD includes the recess RC-PD, a defect caused by slips in the bonding process of the display panel DP (see FIG. 8) and the circuit board FCB (see FIG. 8) may be prevented. In addition, particularly when the conductive particle CB (see FIG. 9) include a low-melting point alloy, a more stable contact structure may be provided.

The display panels DP-13a, DP-13b, DP-13c, DP-13d and DP-13e in FIGS. 13A to 13E may each have a structure in which the pad electrode PD is formed and an etch stopper layer EST is formed thereon.

In an embodiment shown in FIG. 13A, the etch stopper layer EST may be disposed below a second layer ILb (e.g., directly therebelow in a direction opposite to the third direction DR3), and the first layer ILa (see FIG. 9) may be included in the first pad insulating layer PD-IL1 (see FIG. 8) which defines the first pad insulating layer opening portion OP-IL1 (see FIG. 9). In an embodiment, the etch stopper layer EST may not include the opening portion OP-EST and may cover an entirety of an upper surface and lateral edges of the pad electrode PD.

The recess RC-PD of the pad electrode PD in FIG. 13B may have a structure further recessed than that in FIG. 13A (e.g., in a third direction DR3). In an embodiment shown in FIG. 13B, the etch stopper layer EST may be disposed below a third layer ILc (e.g., disposed directly therebelow in a direction opposite to the third direction DR3), and the first layer ILa (see FIG. 9) and the second layer ILb (see FIG. 9) may be included in the first pad insulating layer PD-IL1 (see FIG. 8) which defines the first pad insulating layer opening portion OP-IL1 (see FIG. 9).

In an embodiment shown in FIG. 13C, the etch stopper layer EST may be disposed below a second layer ILb (e.g., disposed directly therebelow in the third direction DR3), and the first layer ILa (see FIG. 9) may be included in the first pad insulating layer PD-IL1 (see FIG. 8) which defines the first pad insulating layer opening portion OP-IL1 (see FIG. 9). A shape of the pad electrode PD may vary depending on a shape of the first layer ILa (see FIG. 9) having been disposed below the pad electrode PD and then removed in the wet etching process. A surface area of a non-recessed portion of the pad electrode PD in FIG. 13C may be less than a surface area of a non-recessed portion of the pad electrode PD in FIG. 13A.

In an embodiment shown in FIG. 13D, the etch stopper layer EST may be disposed below a third layer ILc (e.g., disposed directly therebelow in the third direction DR3), and the first and second layers ILa and ILb (see FIG. 9) may be included in the first pad insulating layer PD-IL1 (see FIG. 8) which defines the first pad insulating layer opening portion OP-IL1 (see FIG. 9). A shape of the pad electrode PD may vary depending on a shape of the first and second layers ILa and ILb (see FIG. 9) having been disposed below the pad electrode PD and then removed in the wet etching process. A surface area of a non-recessed portion of the pad electrode PD in FIG. 13D may be less than a surface area of a non-recessed portion of the pad electrode PD in FIG. 13B.

The display panel DP-3e in FIG. 13E may have a structure in which the etch stopper layer EST is disposed below a first layer Ila (e.g., disposed directly therebelow in a direction opposite to the third direction DR3). In the display panel DP-3e in FIG. 13E, at least one insulating layer may be patterned on a portion in which the recess RC-PD of the pad electrode PD is formed. The pad electrode PD may be formed on the patterned insulating layer. Then, the etch stopper layer EST and a second pad insulating layer PD-IL2 may be formed on the pad electrode PD (e.g., formed directly thereon in the third direction DR3), and a wet etching process may be performed to form the display panel DP-3e. A portion of the etch stopper layer EST may be disposed directly below the non-recessed portion of the pad electrode PD and another portion of the etch stopper layer EST may be disposed directly above the pad electrode PD.

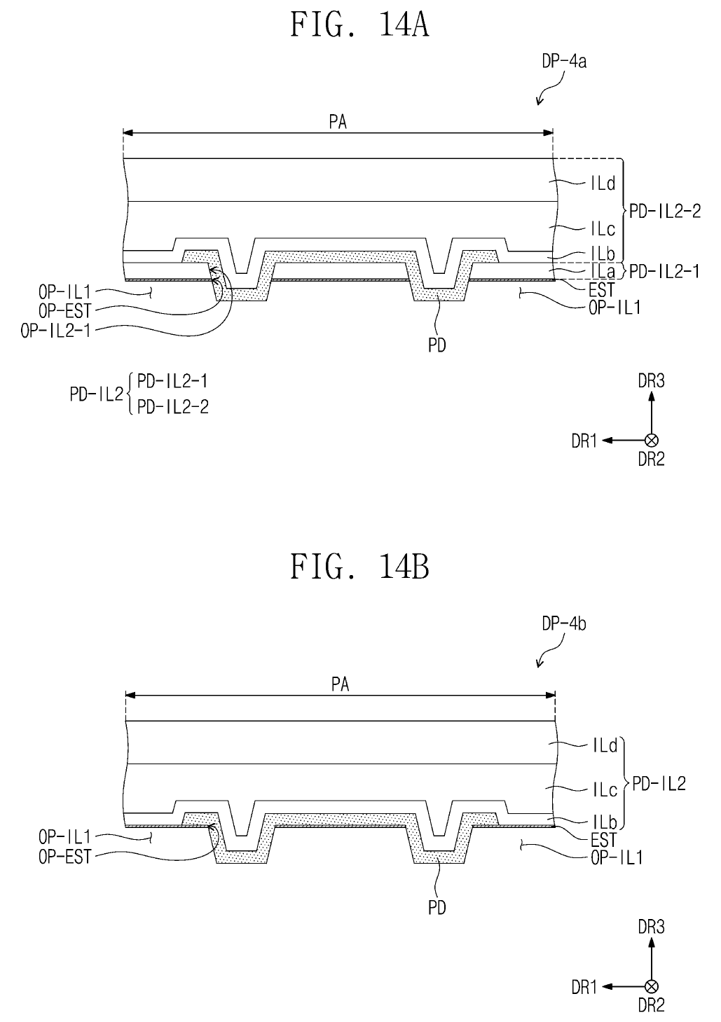

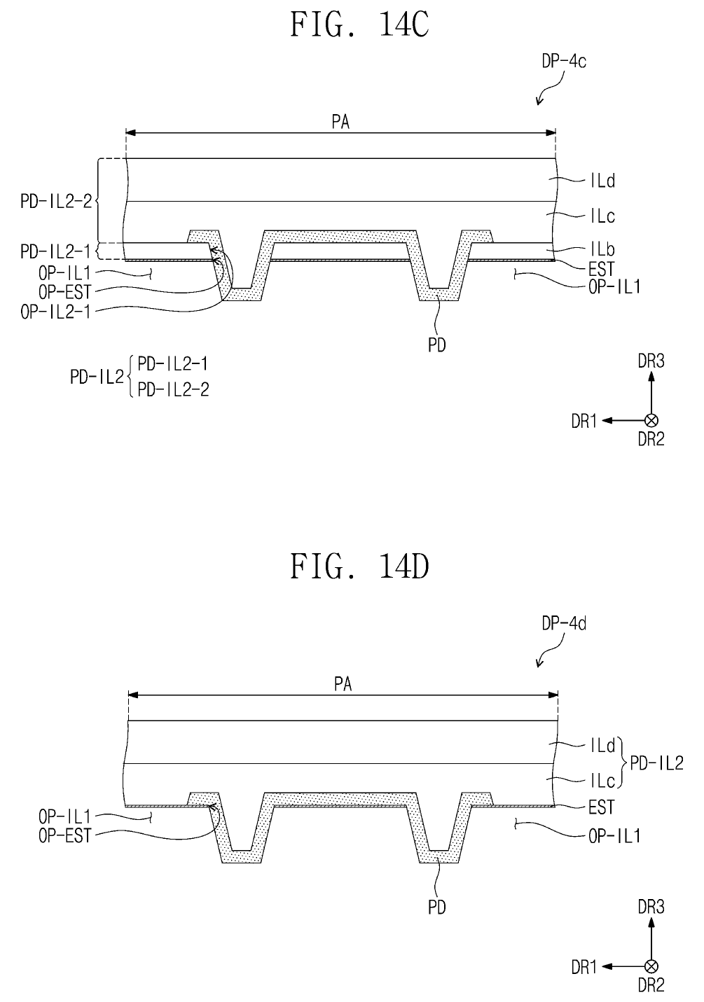

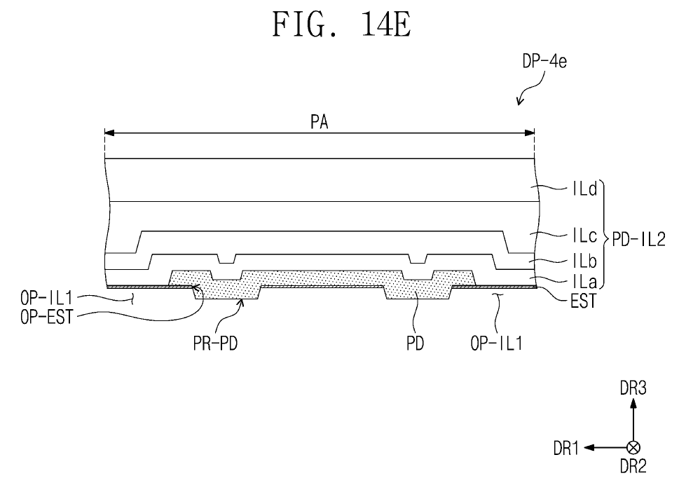

Referring to FIGS. 14A to 14E, display panels DP-4a, DP-4b, DP-4c, DP-4d and DP-4e according to an embodiment may each have a structure including a protrusion PR-PD on an edge of a pad electrode PD when viewed on a cross-section. A contact area may be increased to increase the adhesion, reduce the contact resistance, and prevent a slip defect.

The display panel DP-4a in an embodiment shown in FIG. 14A may have the same structure as that in FIG. 11B, but have a structure including the protrusion PR-PD on the edge (e.g., opposing lateral edges) of the pad electrode PD when viewed on a cross-section. A non-protrusion portion may be overlapped by a (2-1)-th pad insulating layer PD-IL2-1 and an etch stopper layer EST (e.g., in a direction opposite to the third direction DR3), and the protrusion PR-PD may be exposed by a (2-1)-th pad insulating layer opening portion OP-IL2-1 and an etch stopper layer opening portion OP-EST.

The display panel DP-4b in an embodiment shown in FIG. 14B may have the same structure as that in FIG. 12A, but have a structure including the protrusion PR-PD on only the edge (e.g., opposing lateral edges) of the pad electrode PD when viewed on a cross-section. A non-protrusion portion may be overlapped by an etch stopper layer EST (e.g., in a direction opposite to the third direction DR3), and the protrusion PR-PD may be exposed by an etch stopper layer opening portion OP-EST.

The display panel DP-4c in an embodiment shown in FIG. 14C may have the same structure as that in FIG. 12C, but have a structure including the protrusion PR-PD on only the edge (e.g., opposing lateral edges) of the pad electrode PD when viewed on a cross-section. A non-protrusion portion may be overlapped by a (2-1)-th pad insulating layer PD-IL2-1 and an etch stopper layer EST (e.g., in a direction opposite to the third direction DR3), and the protrusion PR-PD may be exposed by a (2-1)-th pad insulating layer opening portion OP-IL2-1 and an etch stopper layer opening portion OP-EST.

The display panel DP-4d in an embodiment shown in FIG. 14D may have the same structure as that in FIG. 12D, but have a structure including the protrusion PR-PD on only the edge (e.g., opposing lateral edges) of the pad electrode PD when viewed on a cross-section. A non-protrusion portion may be covered by an etch stopper layer EST, and the protrusion PR-PD may be exposed by an etch stopper layer opening portion OP-EST.

The display panel DP-4e in an embodiment shown in FIG. 14E may have the same structure as that in FIG. 11A, but have a structure including the protrusion PR-PD on the edge (e.g., opposing lateral edges) of the pad electrode PD when viewed on a cross-section. A non-protrusion portion may be covered by an etch stopper layer EST, and the protrusion PR-PD may be exposed by an etch stopper layer opening portion OP-EST.

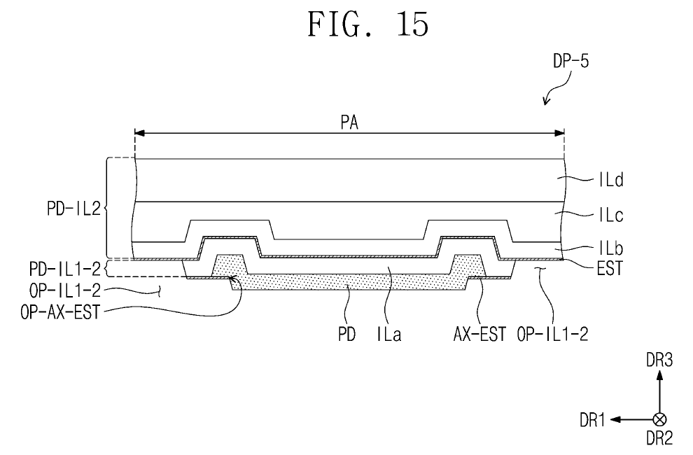

Referring to FIG. 15, the circuit layer DP-CL (see FIG. 8) may further include an auxiliary etch stopper layer AX-EST. In an embodiment, the first pad insulating layer PD-IL1 (see FIG. 8) may include a (1-1)-th pad insulating layer and a (1-2)-th pad insulating layer PD-IL1-2 disposed on the (1-1)-th pad insulating layer. Here, the (1-1)-th pad insulating layer may mean an insulating layer which is disposed below an etch stopper layer EST and in direct contact with the base layer BL, and in which an opening portion corresponding to the base layer opening portion OP-BL (see FIG. 8) is defined. In addition, the (1-2)-th pad insulating layer PD-IL1-2 may mean an insulating layer which is disposed below the etch stopper layer EST (e.g., directly therebelow in a direction opposite to the third direction DR3), and in which a (1-2)-th pad insulating layer opening portion OP-IL1-2 overlapping the base layer opening portion OP-BL (see FIG. 9) but non-overlapping a pad electrode PD is defined. For example, the (1-2)-th pad insulating layer PD-IL1-2 may mean a layer which is not removed even from the inside of the pad electrode PD but remains in an area overlapping the pad electrode PD (e.g., in the third direction DR3). The (1-2)-th pad insulating layer PD-IL1-2 may be disposed below the etch stopper layer EST, and the pad electrode PD may be disposed below the (1-2)-th pad insulating layer PD-IL1-2. The (1-2)-th pad insulating layer opening portion OP-IL1-2 may be defined so as to surround the pad electrode PD. The auxiliary etch stopper layer AX-EST may be disposed below the (1-2)-th pad insulating layer PD-IL1-2 and overlap a non-protrusion portion of the pad electrode PD (e.g., in a direction opposite to the third direction DR3). In an embodiment, the auxiliary etch stopper layer AX-EST may include an auxiliary etch stopper layer opening portion OP-AX-EST which exposes a protrusion of the pad electrode PD. A thickness (e.g., length in the third direction DR3) of the auxiliary etch stopper layer AX-EST may be less than a thickness (e.g., length in the third direction DR3) of the etch stopper layer EST. The auxiliary etch stopper layer AX-EST may not overlap the (1-2)-th pad insulating layer opening portion OP-IL1-2 on a plane. A display panel DP-5 in FIG. 15 may further include the auxiliary etch stopper layer AX-EST, and thus the pad electrode PD may have a structure further protruding from the etch stopper layer EST.

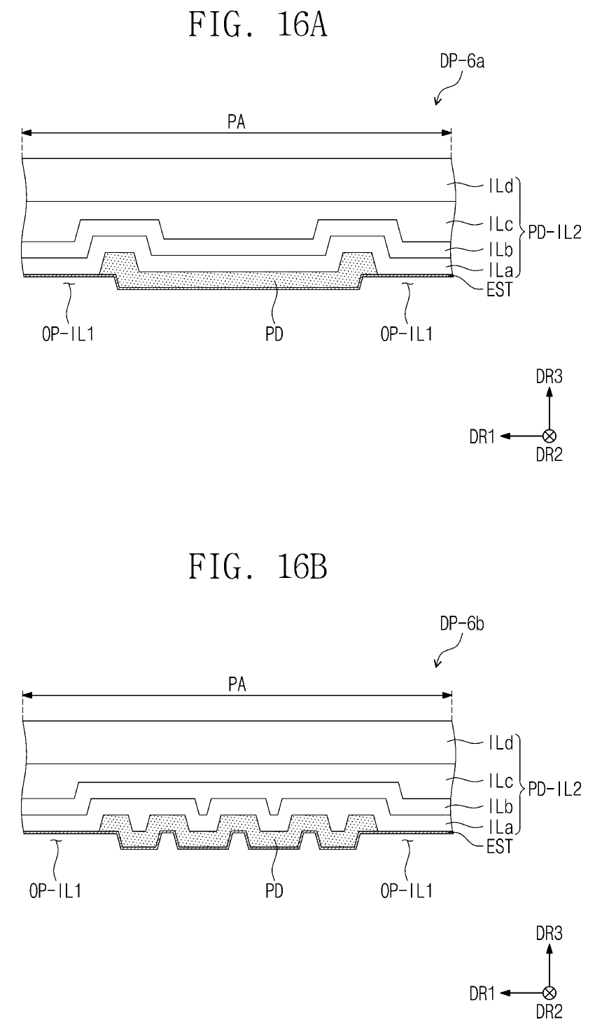

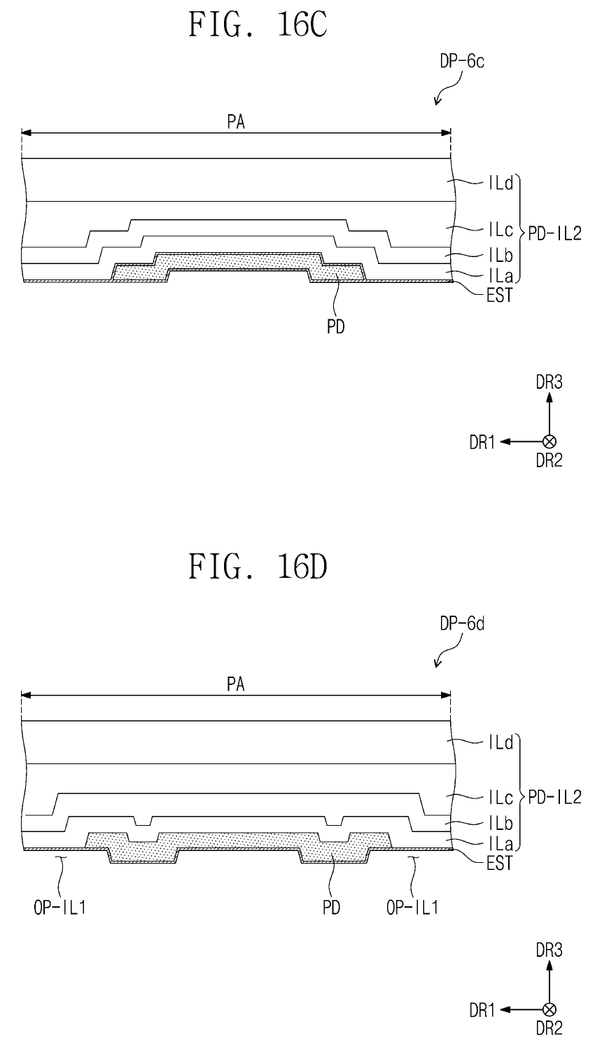

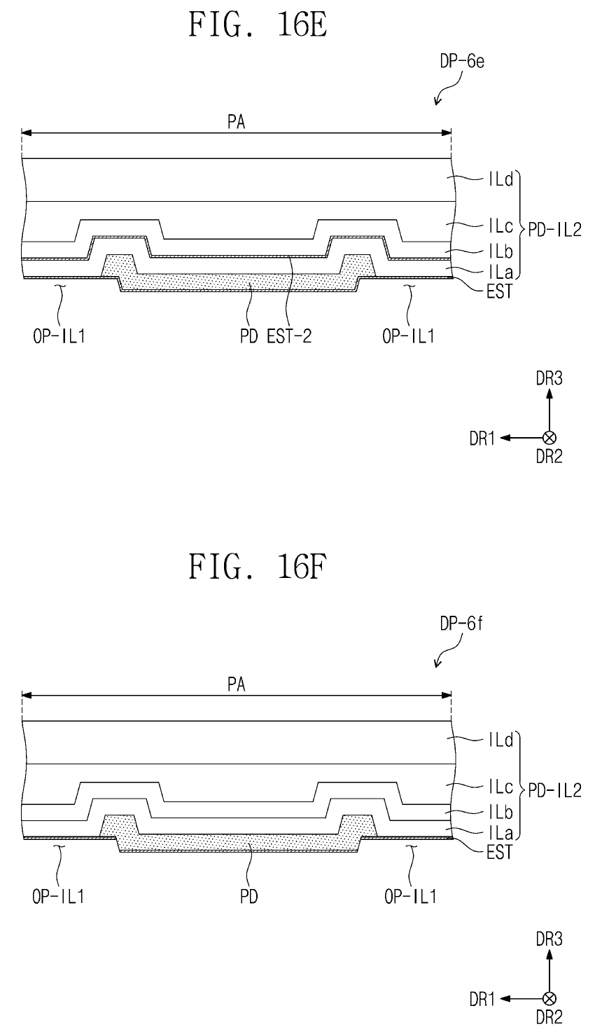

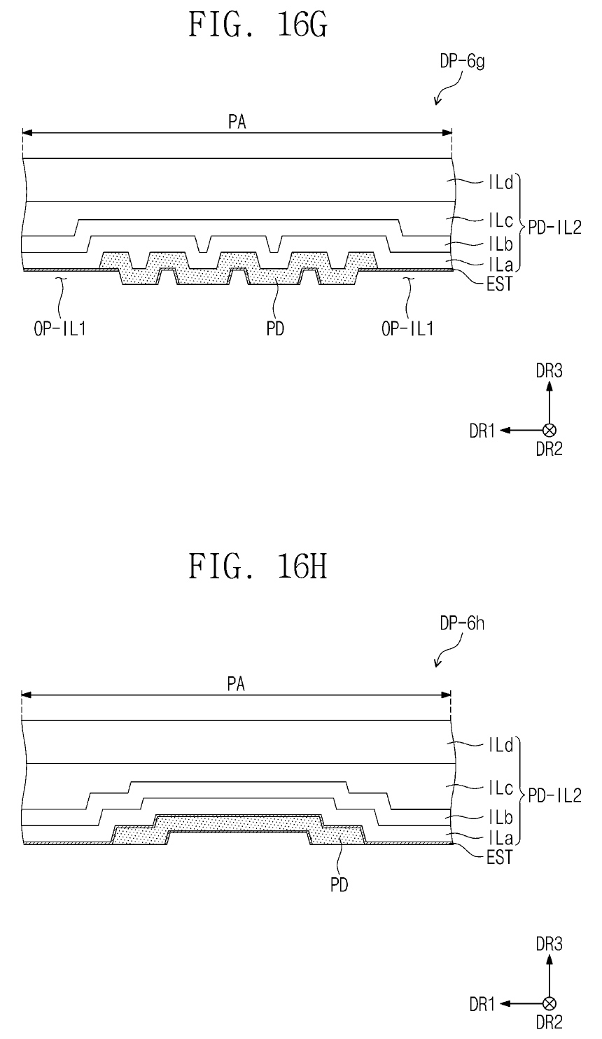

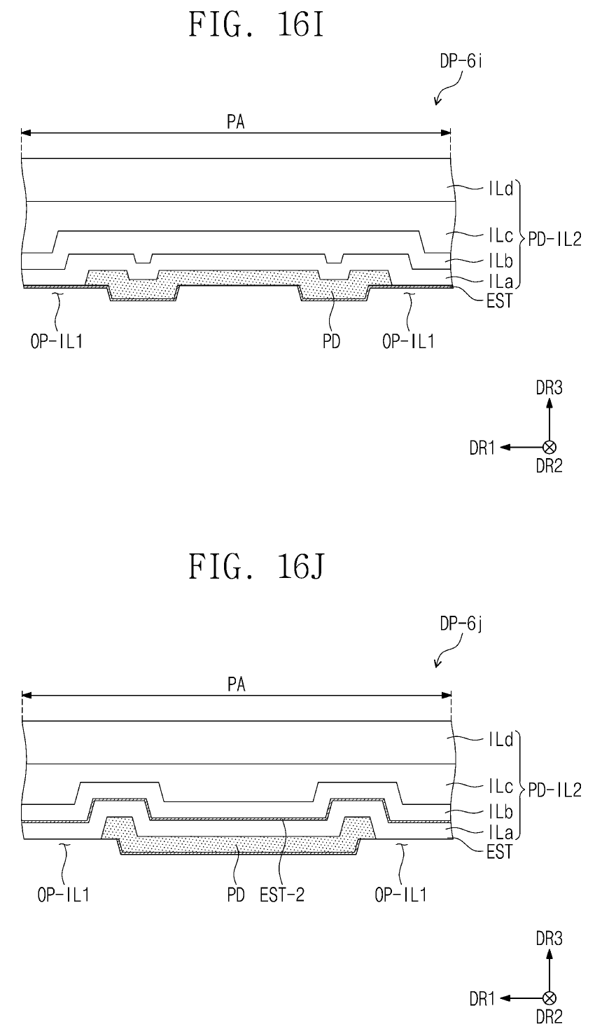

Referring to FIGS. 16A to 16E, a pad electrode PD of a display panel DP-6a, DP-6b, DP-6c, DP-6d or DP-6e according to an embodiment may be overlapped by an etch stopper layer EST (e.g., in a direction opposite to the third direction DR3). The pad electrode PD in FIGS. 16A to 16E may be formed after the etch stopper layer EST is formed. The etch stopper layer EST in FIGS. 16A to 16E may be disposed below a first layer ILa and the pad electrode PD. In an embodiment, the etch stopper layer EST may not include an opening, such as the etch stopper layer opening portion OP-EST.

The pad electrode PD in FIG. 16A may have a protruding structure (e.g., in a direction opposite to the third direction DR3). The pad electrode PD in FIG. 16B may have a plurality of protruding structures. The pad electrode PD in FIG. 16C may have a recessed structure (e.g., in the third direction DR3). The pad electrode PD in FIG. 16D may have a structure in which an edge (e.g., opposing lateral edges) protrudes. The display panel DP-6e in FIG. 16E may further include an additional etch stopper layer EST-2. The additional etch stopper layer EST-2 may be disposed between insulating layers included in a second pad insulating layer PD-IL2 disposed on the etch stopper layer EST. As an example, FIG. 16E illustrates the additional etch stopper layer EST-2 disposed between the first layer ILa and a second layer ILb, but the additional etch stopper layer EST-2 is not necessarily limited thereto.

Referring to FIGS. 16F to 16J, a pad electrode PD of a display panel DP-6f, DP-6g, DP-6h, DP-6i or DP-6j according to an embodiment may have a portion covered by an etch stopper layer EST, and a portion exposed without being covered by the etch stopper layer EST.

The pad electrode PD in FIG. 16F may have a protruding structure (e.g., in a direction opposite to the third direction DR3). The pad electrode PD in FIG. 16G may have a plurality of protruding structures. The pad electrode PD in FIG. 16H may have a recessed structure (e.g., in the third direction DR3). The pad electrode PD in FIG. 16I may have a structure in which an edge (e.g., opposing lateral edges) protrudes. The display panel DP-6j in FIG. 16J may further include an additional etch stopper layer EST-2. The additional etch stopper layer EST-2 may be disposed between insulating layers included in a second pad insulating layer PD-IL2 disposed on the etch stopper layer EST. As an example, FIG. 16J illustrates the additional etch stopper layer EST-2 disposed between a first layer ILa and a second layer ILb, but the additional etch stopper layer EST-2 is not necessarily limited thereto.

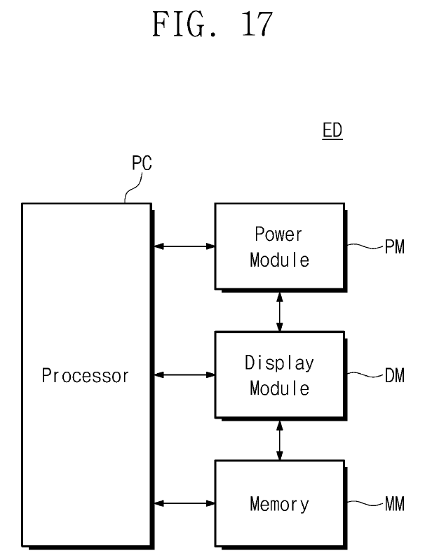

FIG. 17 is a block diagram of an electronic device ED according to an embodiment of the present inventive concept.

Referring to FIG. 17, the electronic device ED according to an embodiment of the present inventive concept may include a display module DM, a processor PC, a memory MM, and a power module PM.

The processor PC may include at least one of a central processing unit (CPU), an application processor (AP), a graphic processing unit (GPU), a communication processor (CP), an image signal processor (ISP), or a controller.

The memory MM may store data information necessary for an operation of the processor PC or the display module DM. When the processor PC executes an application stored in the memory MM, an image data signal and/or an input control signal may be transmitted to the display module DM, and the display module DM may process the received signal and output image information through a display screen.

The power module PM may include a power supply module such as a power adapter or a battery device, and a power conversion module which converts the power supplied by the power supply module and generates power necessary for an operation of the electronic device ED.

At least one of the foregoing components of the electronic device ED may be included in the display device DD (see FIG. 2) according to an embodiment. In addition, some of individual modules included as functional in one module may be included in the display device, and others may be provided separately from the display device (see FIG. 2). For example, the display device (see FIG. 2) may include the display module DM, and the processor PC, the memory MM, and the power module PM may be provided not in the display device DD (see FIG. 2) but in another type of device in the electronic device ED.

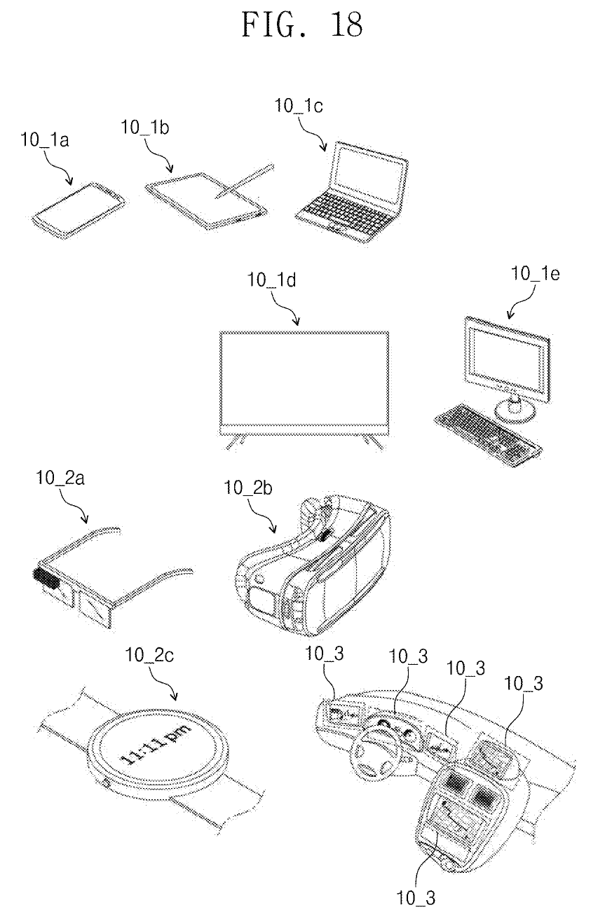

FIG. 18 is a schematic view of electronic devices ED according to various embodiments of the present inventive concept.

Referring to FIG. 18, various electronic devices ED according to embodiments, to which the display device DD (see FIG. 2) is applied, may include not only an electronic device for image display, e.g., a smartphone 10_1a, a tablet PC 10_1b, a laptop computer 10_1c, TV 10_1d, and a monitor for a desk computer 10_1e, but also a wearable electronic device including a display module, e.g., smart glasses 10_2a, a head mounted display 10_2b, and a smart watch 10_2c, and a vehicle electronic device 10_3 including a display module, e.g., a vehicle instrument panel, a center fascia, a center information display (CID) disposed on a dashboard, and a room mirror display. However, embodiments of the present disclosure are not necessarily limited thereto and the electronic devices ED which the display device DD is applied to may include various other small-sized, medium-sized and large-sized electronic devices.

As described above, the display device according to the present inventive concept may have the large contact area between the pad electrode of the display panel and the bump electrode of the circuit board, and compensate for the stepped portion of the bump electrode. Accordingly, the display device may exhibit the excellent adhesion and the reduced contact resistance to increase the bonding reliability.

In the above, description has been made with reference to embodiments of the present inventive concept, but those skilled or of ordinary skill in the art may understand that various modifications and changes may be made to the present inventive concept insofar as such modifications and changes do not depart from the spirit and technical scope of the present inventive concept set forth in the claims to be described later.

What is claimed is:

1. A display device comprising:
a display panel including a display area and a non-display area adjacent to the display area, the non-display area including a pad area; and
a circuit board electrically connected to the display panel,
wherein the display panel comprises:
a light emitting element layer comprising a light emitting element;
a circuit layer disposed below the light emitting element layer, the circuit layer comprising a top surface in contact with the light emitting element layer and a bottom surface opposing the top surface; and
a base layer disposed below the circuit layer, the base layer including a base layer opening portion overlapping the pad area and exposing a portion of the bottom surface of the circuit layer,
wherein the circuit layer comprises:
a first pad insulating layer directly contacting the base layer, the first pad insulating layer including a first pad insulating layer opening portion corresponding to the base layer opening portion; and
an etch stopper layer disposed on the first pad insulating layer, the etch stopper layer having a portion exposed by the first pad insulating layer opening portion,
wherein the display panel further comprises a pad electrode disposed inside the first pad insulating layer opening portion and comprising a protrusion protruding in a direction from the light emitting element layer towards the circuit layer.

2. The display device of claim 1, wherein the circuit layer further comprises a second pad insulating layer disposed above the etch stopper layer.

3. The display device of claim 2, wherein:
the pad electrode is disposed below the second pad insulating layer; and
the etch stopper layer includes an etch stopper layer opening portion exposing the pad electrode.

4. The display device of claim 3, wherein:
the first pad insulating layer comprises at least one inorganic layer; and
the second pad insulating layer comprises at least one organic layer.

5. The display device of claim 4, wherein the second pad insulating layer further comprises at least one inorganic layer disposed below the at least one organic layer.

6. The display device of claim 4, wherein the first pad insulating layer further comprises at least one organic layer disposed above the at least one inorganic layer.

7. The display device of claim 3, wherein the etch stopper layer opening portion includes a plurality of etch stopper layer opening portions.

8. The display device of claim 2, wherein the second pad insulating layer comprises:
a (2-1)-th pad insulating layer in direct contact with the etch stopper layer; and
a (2-2)-th pad insulating layer disposed above the (2-1)-th pad insulating layer,
the pad electrode is disposed below the (2-2)-th pad insulating layer,
the etch stopper layer includes an etch stopper layer opening portion exposing the pad electrode, and
the (2-1)-th pad insulating layer includes a (2-1)-th pad insulating layer opening portion corresponding to the etch stopper layer opening portion.

9. The display device of claim 8, wherein:
the etch stopper layer opening portion includes a plurality of etch stopper layer opening portions; and
the (2-1)-th pad insulating layer opening portion includes a plurality of (2-1)-th pad insulating layer opening portions, each of the plurality of (2-1)-th pad insulating layer opening portions corresponding to each of the plurality of etch stopper layer opening portions.

10. The display device of claim 2, wherein the pad electrode is disposed between the second pad insulating layer and the etch stopper layer.

11. The display device of claim 10, wherein the etch stopper layer includes an etch stopper layer opening portion exposing a portion of the pad electrode.

12. The display device of claim 2, wherein the first pad insulating layer comprises:
a (1-1)-th pad insulating layer in direct contact with the base layer; and
a (1-2)-th pad insulating layer disposed on the (1-1)-th pad insulating layer,
wherein the pad electrode is disposed below the (1-2)-th pad insulating layer,
the (1-1)-th pad insulating layer includes a first pad insulating layer opening portion, and
the (1-2)-th pad insulating layer includes a (1-2)-th pad insulating layer opening portion overlapping the first pad insulating layer opening portion and surrounding the pad electrode.

13. The display device of claim 12, wherein:
the circuit layer further comprises an auxiliary etch stopper layer disposed between the (1-1)-th pad insulating layer and the (1-2)-th pad insulating layer, the auxiliary etch stopper layer having a thickness that is less than a thickness of the etch stopper layer;
the auxiliary etch stopper layer does not overlap the (1-2)-th pad insulating layer opening portion on a plane, and
the auxiliary etch stopper layer includes an auxiliary etch stopper layer opening portion exposing the pad electrode.

14. The display device of claim 1, wherein:
the base layer comprises a glass substrate;
the etch stopper layer comprises amorphous silicon, silicon nitride, or polyimide; and
the pad electrode comprises molybdenum, tungsten, titanium, or amorphous silicon.

15. The display device of claim 1, further comprising an adhesive layer disposed between the display panel and the circuit board,
wherein the circuit board comprises a base film, and a bump electrode disposed on the base film and overlapping the pad electrode on a plane, and
the adhesive layer comprises:
an adhesive resin in direct contact with each of the display panel and the circuit board; and
a conductive particle disposed in the adhesive resin and electrically connected to the pad electrode and the bump electrode.

16. A display device comprising:
a display panel including a display area and a non-display area adjacent to the display area, the non-display area including a pad area; and
a circuit board electrically connected to the display panel,
wherein the display panel comprises:
a light emitting element layer comprising a light emitting element;
a circuit layer disposed below the light emitting element layer, the circuit layer comprising a top surface in contact with the light emitting element layer and a bottom surface opposing the top surface; and
a base layer disposed below the circuit layer, the base layer including a base layer opening portion overlapping the pad area and exposing a portion of the bottom surface of the circuit layer,
wherein the circuit layer comprises:
a first pad insulating layer directly contacting the base layer, the first pad insulating layer including a first pad insulating layer opening portion corresponding to the base layer opening portion; and
an etch stopper layer disposed on the first pad insulating layer, the etch stopper layer having a portion exposed by the first pad insulating layer opening portion,
wherein the display panel further comprises a pad electrode disposed inside the first pad insulating layer opening portion and comprising a recess recessed in a direction from the circuit layer towards the light emitting element layer.

17. The display device of claim 16, wherein the circuit layer further comprises:
a second pad insulating layer disposed above the etch stopper layer; and
the pad electrode is disposed below the etch stopper layer.

18. The display device of claim 17, wherein:
the first pad insulating layer comprises at least one inorganic layer; and
the second pad insulating layer comprises at least one organic layer.

19. The display device of claim 16, wherein:
the base layer comprises a glass substrate;
the etch stopper layer comprises amorphous silicon, silicon nitride, or polyimide; and
the pad electrode comprises molybdenum, tungsten, titanium, or amorphous silicon.

20. An electronic device comprising:
a display panel including a display area and a non-display area adjacent to the display area, the non-display area including a pad area;
a circuit board disposed below the display panel and electrically connected to the display panel;
a window disposed on the display panel, and comprising a transmission area overlapping the display area and a bezel area overlapping the non-display area; and
a housing disposed below the display panel to accommodate the display panel and the circuit board, and coupled to the window,
wherein the display panel comprises:
a light emitting element layer comprising a light emitting element;
a circuit layer disposed below the light emitting element layer, the circuit layer comprising a top surface in contact with the light emitting element layer and a bottom surface opposing to the top surface; and
a base layer disposed below the circuit layer, the base layer including a base layer opening portion overlapping the pad area and exposing a portion of the bottom surface of the circuit layer,
wherein the circuit layer comprises:
a first pad insulating layer directly contacting the base layer, and the first pad insulating layer including a first pad insulating layer opening portion corresponding to the base layer opening portion;
an etch stopper layer disposed on the first pad insulating layer, the etch stopper layer having a portion exposed by the first pad insulating layer opening portion; and
a second pad insulating layer disposed on the etch stopper layer,
wherein the display panel further comprises a pad electrode disposed inside the first pad insulating layer opening portion.
